(19) United States
(12) Patent Application Publication
(10) Pub. No.: US 2026/0038574 A1
(43) Pub. Date: Feb. 5, 2026

(54) METHOD FOR ALLEVIATING LEAKAGE DEGRADATION EFFECT IN GaN DEVICE

(71) Applicant: Wenzhou University, Zhejiang (CN)

(72) Inventors: Pengjun WANG, Zhejiang (CN); Shutong Zhang, Zhejiang (CN); Yue Jun ZHANG, Zhejiang (CN); Ziyu Zhou, Zhejiang (CN); Cai Long Jin, Zhejiang (CN)

(73) Assignee: Wenzhou University, Zhejiang (CN)

(21) Appl. No.: 19/290,324

(22) Filed: Aug. 4, 2025

(30) Foreign Application Priority Data
Aug. 5, 2024 (CN) 202411063756.0

(51) Int. Cl. G11C 11/4078; G11C 11/406; G11C 11/4072; G11C 11/4076; H03K 19/0944; H03K 19/21

(52) U.S. Cl. CPC G11C 11/4078; G11C 11/40615; G11C 11/4072; G11C 11/4076; H03K 19/0944; H03K 19/215

(57) ABSTRACT

A low-overhead encryption and decryption circuit based on hardware multiplexing includes a secure storage array, a timing control module, a key row, a sensitive amplifier array, an inverter array, an on-off control array, a write circuit and two refresh circuits. The secure storage array is configured to store data to be encrypted, XOR data and decrypted data and encrypt and decrypt data, and is realized based on the hardware multiplexing technique, thereby reducing hardware overheads; the key row, when needed to generate keys, generates the keys under the control of the timing control circuit and when not used, is controlled by the timing control circuit to be powered off and reset, and the key row adopts a dynamic key generation technique and avoids the unsecure behavior of key storage, thereby having high security.

### CROSS-REFERENCE TO RELATED APPLICATIONS

This application claims the priority benefit of China application serial no. 202411063756.0, filed on Aug. 5, 2024. The entirety of the above-mentioned patent application is hereby incorporated by reference herein and made a part of this specification.

### TECHNICAL FIELD

The invention relates to an encryption and decryption circuit, in particular to a low-overhead encryption and decryption circuit based on hardware multiplexing.

### DESCRIPTION OF RELATED ART

At present, a large quantity of privacy data collected by the Internet of Things is exposed to the risk of authorized access and stealing. To improve the data security of the Internet of Things, encryption and decryption circuits are designed by researchers.

Encryption and decryption circuits that are widely used at present adopt an AES encryption and decryption circuit structure. As required by such encryption and decryption circuits, not only an encrypted plaintext, but also a 128-bit AES key needs to be input, so the key needs to be specially stored and managed with a complex process, and the key will be stolen by attackers even in case of a small bug, leading to poor security; in addition, XOR encryption and decryption operations need to be performed on the plaintext and the key during encryption and decryption, and a hardware module used for the XOR encryption and decryption operations needs to be additionally configured, leading a high overall hardware cost.

### SUMMARY

The technical issue to be settled by the invention is to provide a low-overhead encryption and decryption circuit based on hardware multiplexing, which has low hardware overheads and good security.

The technical solution adopted by invention to settle the above technical issue is as follows. A low-overhead encryption and decryption circuit based on hardware multiplexing includes a secure storage array, a timing control module, a key row, a sensitive amplifier array, an inverter array, an on-off control array, a write circuit and two refresh circuits. The two refresh circuits are referred to as a first refresh circuit and a second refresh circuits, respectively. The secure storage array is realized based on a hardware multiplexing technique to reduce overheads of hardware resources. When encryption is needed, firstly, the timing control module controls the second refresh circuit to output a reset signal to refresh the secure storage array to reset the state of the secure storage array. Then, when data to be encrypted are transmitted to the write circuit, the write circuit, under the control of the timing control module, converts the data to be encrypted into two types of data with opposite phases and outputs the two types of data with opposite phases to the secure storage array, and the secure storage array stores the two types of data with opposite phases, output from the write circuit. Then, the timing control module, on one hand, controls the first refresh circuit to output a pre-charge signal to pre-charge the secure storage array, and on the other and, controls the second refresh circuit to output a reset signal to refresh the key row to reset the state of the key row. Then, the timing control module controls the key row to generate a pair of keys with opposite phases and transmits the pair of keys with opposite phases to the on-off control array; the on-off control array transmits the pair of keys with opposite phases, transmitted from the key row, to the secure storage array. The secure storage array performs an XOR operation on the pair of keys currently transmitted from the key row and the two types of data with opposite phases stored in the secure storage array to obtain a one-bit XOR value and transmits the XOR value to the sensitive amplifier array. The sensitive amplifier array, under the control of the timing control module, shapes the XOR value output from the secure storage array to obtain a shaped XOR value and transmits the shaped XOR value to the inverter array. The inverter array performs a phase inversion on the shaped XOR value to obtain an XOR value with an opposite phase and transmits the XOR value with the opposite phase to the on-off control array. The on-off control array transmits the shaped XOR value transmitted from the sensitive amplifier array and the XOR value with the opposite phase reversely transmitted from the inverter array to the secure storage array; and the secure storage array stores the shaped XOR value and the XOR value with the opposite phase as encrypted data, such that encryption is realized. When the encrypted data stored in the secure storage array need to be decrypted, firstly, the timing control module, on one hand, controls the first refresh circuit to output a pre-charge signal to pre-charge the secure storage array, and on the other hand, controls the second refresh circuit to output a reset signal to refresh the key row to reset the state of the key row. Then, the timing control module controls the key row to generate the pair of keys with opposite phases and transmits the pair of keys with opposite phases to the on-off control array. The on-off control array transmits the pair of keys with opposite phases transmitted from the key row to the secure storage array. The secure storage array performs an XOR operation on the pair of keys with opposite phases received currently and the encrypted data stored in the secure storage array to obtain a one-bit initial value and transmits the one-bit initial value to the sensitive amplifier array. The sensitive amplifier array, under the control of the timing control module, shapes the initial value to obtain a shaped initial value and transmits the shaped initial value to the inverter array. The inverter array performs the phase inversion on the shaped initial value to obtain an initial value with an opposite phase and transmits the initial value with the opposite phase to the on-off control array. The on-off control array transmits the one-bit initial value output from the sensitive amplifier array and the initial value with the opposite phase output from the inverter array to the secure storage array; and the secure storage array stores the one-bit initial value and the initial value with the opposite phase, and at this moment, the pair of data stored in the secure storage array is the same as the pair of data input by the write circuit during encryption, such that data decryption is realized.

The write circuit has a group of input terminals, two groups of output terminals and a control terminal. In the write circuit, four-bit binary data are input to the group of input terminals, each group of the two groups of output terminals is configured to output four-bit binary data, the group of input terminals is referred to as a first group of input terminals, the two groups of output terminals are referred to as a first group of output terminals and a second group of output terminals, respectively, and the control terminal is referred to as a first control terminal. The first refresh circuit has two input terminals and three groups of output terminals. In the first refresh circuit, the two input terminals are referred to as a first input terminal and a second input terminal respectively, each group of the three groups of output terminals is configured to output four-bit binary data, and the three groups of output terminals are referred to as a first group of output terminals, a second group of output terminals and a third group of output terminals, respectively. The second refresh circuit has two input terminals and four groups of output terminals. In the second refresh circuit, the two input terminals are referred to as a first input terminal and a second input terminal, respectively, each group of the four groups of output terminals is configured to output four-bit binary data, the four groups of output terminals are referred to as a first group of output terminals, a second group of second output terminals, a third group of output terminals and a fourth group of output terminals, respectively. The sensitive amplifier array has two input terminals, a group of input terminals and a group of output terminals. In the sensitive amplifier array the two input terminals are referred to as a first input terminal and a second terminal, respectively, four-bit binary data are input to the group of input terminals, the group of input terminals is referred to as a first group of input terminal, and the group of output terminals is configured to output four-bit binary data and referred to as a first group of output terminals. The secure storage array has five groups of input terminals and three groups of input-output terminals. In the secure storage array, four-bit binary data are input to each group of the five groups of input terminals, each group of the three groups of input-output terminals is configured to output four-bit binary data or allow four-bit binary data to be input to the secure storage array, the five groups of input terminals are referred to as a first group of input terminals, a second group of input terminals, a third group of input terminals, a fourth group of input terminals and a fifth group of input terminals, respectively, and the three groups of input-output terminals are referred to as a first group of input-output terminals, a second group of input-output terminals and a third group of input-output terminals, respectively. The key row has an input terminal, two groups of input-output terminals and a control terminal. In the key row the input terminal is referred to as a first input terminal, each group of the two groups of input-output terminals is configured to output four-bit binary data or allow four-bit binary data to be input to the key row, the two groups of input-output terminals are referred to as a first group of input-output terminals and a second group of input-output terminals, respectively, and the control terminal is referred to as a first control terminal. The inverter array has a group of input terminals and a group of output terminals. In the inverter array four-bit binary data are input to the group of input terminals, the group of output terminals is configured to output four-bit binary data, the group of input terminals is referred to as a first group of input terminals, and the group of output terminals is referred to as a first group of output terminals. The timing control module has ten output terminals. In the timing control module the ten output terminals are referred to as a first output terminal, a second output terminal, a third output terminal, a fourth output terminal, a fifth output terminal, a sixth output terminal, a seventh output terminal, an eighth output terminal, a ninth output terminal and a tenth output terminal, respectively. The timing control module is configured to control the secure storage array, the key row, the sensitive amplifier array, the inverter array, the on-off control array, the write circuit and the two refresh circuits to work coordinately. The first output terminal, the second output terminal, the third output terminal, the fourth terminal and the fifth output terminal of the timing control module are configured to output control signals, respectively. The sixth output terminal, the seventh output terminal, the eighth output terminal, the ninth output terminal and the tenth output terminal of the timing control module are configured to output refresh signals, respectively. The control signal output by the first output terminal of the timing control module is denoted as ctrl0, the control signal output by the second output terminal of the timing control module is denoted as ctrl1, the control signal output by the third output terminal of the timing control module is denoted as ctrl2, the control signal output by the fourth output terminal of the timing control module is denoted as ctrl3, the control signal output by the fifth output terminal of the timing control module is denoted as ctrl4, the refresh signal output by the sixth output terminal of the timing control module is denoted as pre0, the refresh signal output by the seventh output terminal of the timing control module is denoted as pre1, refresh signal output by the eighth output terminal of the timing control module is denoted as pre2, the refresh signal output by the ninth output terminal of the timing control module is denoted as pre3, and the refresh signal output by the tenth output terminal of the timing control module is denoted as pre4. The on-off control array has two groups of input terminals, four groups of output terminals, two groups of input-output terminals and three control terminals. In the on-off control array four-bit binary data are input to each group of the two groups of input terminals, each group of the four groups of output terminals is configured to output four-bit binary data, each group of input-output terminals is configured to output four-bit binary data or allow four-bit binary data to be input to the on-off control array, the two groups of input terminals are referred to as a first group of input terminals and a second group of input terminals, respectively, the four groups of output terminals are referred to as a first group of output terminals, a second group of output terminals, a third group of output terminals and a fourth group of output terminals, respectively, the two groups of input-output terminals are referred to as a first group of input-output terminals and a second group of input-output terminals, respectively, and the three control terminals are referred to as a first control terminal, a second control terminal and a third control terminal, respectively. Four-bit data to be encrypted are denoted as IN<0:3>, the four-bit data IN<0:3> to be encrypted are input to the first group of input terminals of the write circuit, the first group of output terminals of the write circuit is configured to output one of two types of data with opposite phases, the second group of output terminals of the write circuit is configured to output the other one of the two types of data with opposite phases, the first group of output terminals of the write circuit is connected to the first group of input-output terminals of the secure storage array, the first group of output terminals of the second refresh circuit and the first group of output terminals of the on-off control array, the second group of output terminals of the write circuit is connected to the second group of input-output terminals of the secure storage array, the second group of output terminals of the second refresh circuit and the second group of output terminals of the on-off control array, the first control terminal of the write circuit is connected to the first output terminal of the timing control module, the first input terminal of the first refresh circuit is connected to the sixth output terminal of the timing control module, the second input terminal of the first refresh circuit is connected to the seventh output terminal of the timing control module, the first group of output terminals of the first refresh circuit is connected to the third group of input-output terminals of the secure storage array and the first group of input terminals of the sensitive amplifier array, the second group of output terminals of the first refresh circuit is connected to the fourth group of input terminals of the secure storage array and the third group of output terminals of the on-off control array, the second group of output terminals of the first refresh circuit is configured to output a pre-charge signal, which is four-bit binary data, the third group of output terminals of the first refresh circuit is connected to the fifth group of input terminals of the secure storage array and the fourth group of output terminals of the on-off control array, the third group of output terminals of the first refresh circuit is configured to output a pre-charge signal, which is four-bit binary data, the first input terminal of the second refresh circuit is connected to the eighth output terminal of the timing control module, the second input terminal of the second refresh circuit is connected to the tenth output terminal of the timing control module, the third group of output terminals of the second refresh circuit is connected to the first group of input-output terminals of the key row and the first group of input-output terminals of the on-off control array, the third group of output terminals of the second refresh circuit is configured to output a reset signal, which is four-bit binary data, the fourth group of output terminals of the second refresh circuit is connected to the second group of input-output terminals of the key row and the second group of input-output terminals of the on-off control array, the fourth group of output terminals of the second refresh circuit is configured to output a reset signal, which is four-bit binary data. The first input terminal of the sensitive amplifier array is configured to receive an external threshold voltage compare. The first group of output terminals of the sensitive amplifier array is configured to output the shaped XOR value, which is four-bit binary data. The second input terminal of the sensitive amplifier array is connected to the ninth output terminal of the timing control module, the first group of output terminals of the sensitive amplifier array is connected to the first group of input terminals of the inverter array and the first group of input terminals of the on-off control array. The first group of input terminals of the secure storage array is configured to receive a four-bit voltage signal VDD<0:3>. The second group of input terminals of the secure storage array is configured to receive a four-bit word line control signal WL<0:3>. The third group of input terminals of the secure storage array is configured to receive a four-bit on-off control signal ctrl<0:3>. The four-bit voltage signal VDD<0:3> is configured to control power-on and power-off of the secure storage array. The four-bit word line control signal WL<0:3> is configured to control the secure storage array to store or not store data BL<0:3> input to the first input-output terminal of the secure storage array and data BLB<0:3> input to the second input-output terminal of the secure storage array. The four-bit on-off control signal ctrl<0:3> is configured to control the secure storage array to store or not store data input to the fourth input terminal of the secure storage array and data input to the fifth input terminal of the secure storage array. The first control terminal of the key row is connected to the fifth output terminal of the timing control module. The first input terminal of the key row is configured to receive a word line control signal XWL, and the word line control signal XWL is configured to control transmission of keys of the key row. The first group of output terminals of the inverter array is configured to output the shaped XOR value subjected to phase inversion, the first group of output terminals of the inverter array is connected to first group of input terminals of the on-off control array, the first control terminal of the on-off control array is connected to the second output terminal of the timing control module, the second control terminal of the on-off control array is connected to the third output terminal of the timing control module, and the third control terminal of the on-off control array is connected the fourth output terminal of the timing control module.

The write circuit includes four first write cells and four second write cells Each of the four first write cells has an input terminal, an output terminal and a control terminal. Each of the four second write cells has an input terminal, an output terminal and a control terminal. The control terminals of the four first write cells and the control terminals of the four second write cells are connected to a connecting terminal which is the first control terminal of the write circuit. The input terminal of a 1^{st} first write cell and the input terminal of a 1^{st} second write cell are connected to a connecting terminal which is a first input terminal of the write circuit. The input terminal of a 2^{nd} first write cell and the input terminal of a 2^{nd} second write cell are connected to a connecting terminal which is a second input terminal of the write circuit. The input terminal of a 3^{rd} first write cell and the input terminal of a 3^{rd} second write cell are connected to a connecting terminal which is a third input terminal of the write circuit. The input terminal of a 4^{th} first write cell and the input terminal of a 4^{th} second write cell are connected to a connecting terminal which is a fourth input terminal of the write circuit. The first input terminal, the second input terminal, the third input terminal and the fourth input terminal of the write circuit form the first group of input terminals of the write circuit. The output terminal of the 1^{st} first write cell is a first output terminal of the write circuit, the output terminal of the 2^{nd} first write cell is a second output terminal of the write circuit, the output terminal of the 3^{rd} first write cell is a third output terminal of the write circuit, the output terminal of the 4^{th} first write cell is a fourth output terminal of the write circuit, and the first output terminal, the second output terminal, the third output terminal and the fourth output terminal of the write circuit form the first group of output terminals of the write circuit; the output terminal of the 1^{st} second write cell is a fifth output terminal of the write circuit, the output terminal of the 2^{nd} second write cell is a sixth output terminal of the write circuit, the output terminal of the 3^{rd} second write cell is a seventh output terminal of the write circuit, the output terminal of the 4^{th} second write cell is an eighth output terminal of the write circuit, and the fifth output terminal, the sixth output terminal, the seventh output terminal and the eighth output terminal of the write circuit form the second group of output terminals of the write circuit. Each of the four first write cells includes a first PMOS transistor, a second PMOS transistor, a third PMOS transistor, a fourth PMOS transistor, a first NMOS transistor, a second NMOS transistor, a third NMOS transistor and a fourth NMOS transistor. A supply voltage is accessed to a source of the first PMOS transistor, a source of the second PMOS transistor and a source of the third PMOS transistor. A gate of the first PMOS transistor and a gate of the first NMOS transistor are connected to a connecting terminal which is the input terminal of the first write cell. A drain of the first PMOS transistor, a drain of the first NMOS transistor, a gate of the fourth PMOS transistor and a gate of the third NMOS transistor are connected. A drain of the second PMOS transistor, a gate of the third PMOS transistor and a drain of the second NMOS transistor are connected. A gate of the second PMOS transistor, a gate of the second NMOS transistor and a gate of the fourth NMOS transistor are connected to a connecting terminal which is the control terminal of the first write cell. A drain of the third PMOS transistor and a source of the fourth PMOS transistor are connected. A drain of the fourth PMOS transistor and a drain of the third NMOS transistor are connected to a connecting terminal which is the output terminal of the first write cell. A source of the third NMOS transistor and a drain of fourth NMOS transistor are connected. A source of the first NMOS transistor, a source of the second NMOS transistor and a source of the fourth NMOS transistor are grounded. Each of the four second write cells includes a fifth PMOS transistor, a sixth PMOS transistor, a seventh PMOS transistor, a fifth NMOS transistor, a sixth NMOS transistor and a seventh NMOS transistor. A supply voltage is accessed to a source of the fifth PMOS transistor and a source of the sixth PMOS transistor. A gate of the fifth PMOS transistor, a gate of the fifth NMOS transistor and a gate of the seventh NMOS transistor are connected to a connecting terminal which is the control terminal of the second write cell. A drain of the fifth PMOS transistor, a gate of the sixth PMOS transistor and a drain of the fifth NMOS transistor are connected. A drain of the sixth PMOS transistor and a source of the seventh PMOS transistor are connected. A gate of the sixth NMOS transistor and a gate of the seventh PMOS transistor are connected to a connecting terminal which is the input terminal of the second write circuit. A source of the sixth NMOS transistor and a drain of the seventh PMOS transistor are connected to a connecting terminal which is the output terminal of the second write circuit. A drain of the sixth NMOS transistor and a drain of the seventh NMOS transistor are connected; and a source of the seventh NMOS transistor and a source of the fifth NMOS transistor are grounded.

The first refresh circuit includes three first refresh cells. Each of the three first refresh cells has an input terminal and a group of output terminals; the input terminal of a 1^{st} first refresh cell is the first input terminal of the first refresh circuit, and the group of output terminals of the 1^{st} first refresh cell is the first group of output terminals of the first refresh circuit. The input terminal of a 2^{nd} first refresh cell, the input terminal of a 3^{rd} first refresh cell are connected to a connecting terminal which is the second input terminal of the first refresh circuit; the group of output terminals of the 2^{nd} first refresh cell is the second group of output terminals of the first refresh circuit; and the group of output terminals of the 3^{rd} first refresh cell is the third group of output terminals of the first refresh circuit. Each of the three first refresh cells includes an eighth PMOS transistor, a ninth PMOS transistor, a tenth PMOS transistor and an eleventh PMOS transistor. A supply voltage VDD is accessed to a source of the eighth PMOS transistor, a source of the ninth PMOS transistor, a source of the tenth PMOS transistor and a source of the eleventh PMOS transistor. A gate of the eighth PMOS transistor, a gate of the ninth PMOS transistor, a gate of the tenth PMOS transistor and a gate of the eleventh PMOS transistor are connected to a connecting terminal which is the input terminal of the first refresh cell; a drain of the eighth PMOS transistor is a first output terminal of the three first refresh cells, a drain of the ninth PMOS transistor is a second output terminal of the three first refresh cells, a drain of the tenth PMOS transistor is a third output terminal of the three first refresh cells, and a drain of the eleventh PMOS transistor is a fourth output terminal of the three first refresh cells; and the first output terminal, the second output terminal, the third output terminal and the fourth output terminal of the three first refresh cells form the group of output terminals of the three first refresh cells.

The second refresh circuit includes four second refresh cells. Each of the four second refresh cells has an input terminal and a group of output terminals. The input terminal of a 1^{st} second refresh cell and the input terminal of a 2^{nd} second refresh cell are connected to a connecting terminal which is the first input terminal of the second refresh circuit; the input terminal of a 3^{rd} second refresh cell and the input terminal of a 4^{th} second refresh cell are connected to a connecting terminal which is the second input terminal of the second refresh circuit; and the group of output terminals of the 1^{st} second refresh cell is the first group of output terminals of the second refresh circuit, the group of output terminals of the 2^{nd} second refresh cell is the second group of output terminals of the second refresh circuit, the group of output terminals of the 3^{rd} second refresh cell is the third group of output terminals of the second refresh circuit, and the group of output terminals of the 4^{th} second refresh cell is the fourth group of output terminals of the second refresh circuit. Each of the four second refresh cells includes an eighth NMOS transistor, a ninth NMOS transistor, a tenth NMOS transistor and an eleventh NMOS transistor, wherein a source of the eighth NMOS transistor, a source of the ninth NMOS transistor, a source of the tenth NMOS transistor and a source of the eleventh NMOS transistor are grounded; a gate of the eighth NMOS transistor, a gate of the ninth NMOS transistor, a gate of the tenth NMOS transistor and a gate of the eleventh NMOS transistor are connected to a connecting terminal which is the input terminal of the four second refresh cells; a drain of the eighth NMOS transistor is a first output terminal of the four second refresh cells, a drain of the ninth NMOS transistor is a second output terminal of the four second refresh cells, a drain of the tenth NMOS transistor is a third output terminal of the four second refresh cells, and a drain of the eleventh NMOS transistor is a fourth output terminal of the four second refresh cells; and the first output terminal, the second output terminal, the third output terminal and the fourth output terminal of the four second refresh cells form the group of output terminals of the four second refresh cells.

The inverter array includes four inverters. Each of the four inverters has an input terminal and an output terminal. The input terminal of a first inverter is a first input terminal of the inverter array, the input terminal of a second inverter is a second input terminal of the inverter array, the input terminal of a third inverter is a third input terminal of the inverter array, the input terminal of a fourth inverter is a fourth input terminal of the inverter array, and the first input terminal, the second input terminal, the third input terminal and the fourth input terminal of the inverter array form the first group of input terminals of the inverter array. The output terminal of the first inverter is a first output terminal of the inverter array, the output terminal of the second inverter is a second output terminal of the inverter array, the output terminal of the third inverter is a third output terminal of the inverter array, the output terminal of the fourth inverter is a fourth output terminal of the inverter array, and the first output terminal, the second output terminal, the third output terminal and the fourth output terminal of the inverter array forms the first group of output terminals of the inverter array. Each of the four inverters includes a twelfth PMOS transistor and a twelfth NMOS transistor, wherein a supply voltage is accessed to a source of the twelfth PMOS transistor; a gate of the twelfth PMOS transistor and a gate of the twelfth NMOS transistor are connected to a connecting terminal which is the input terminal of the inverter; a drain of the twelfth PMOS transistor and a drain of the twelfth NMOS transistor are connected to a connecting terminal which is the output terminal of the inverter; and a source of the twelfth NMOS transistor is grounded.

The sensitive amplifier array includes four sensitive amplifiers. Each of the four sensitive amplifiers has three input terminals and an output terminal. The three input terminals are referred to as a first input terminal, a second input terminal and a third input terminal, respectively. The first input terminals of the four sensitive amplifiers are connected, and a connecting terminal is the first input terminal of the sensitive amplifier array. The second input terminals of the four sensitive amplifiers are connected to a connecting terminal which is the second input terminal of the sensitive amplifier array. The third input terminal of a first sensitive amplifier is a first input terminal of the sensitive amplifier array, the third input terminal of a second sensitive amplifier is a second input terminal of the sensitive amplifier array, the third input terminal of a third sensitive amplifier is a third input terminal of the sensitive amplifier array, the third input terminal of a fourth sensitive amplifier is a fourth input terminal of the sensitive amplifier array, and first input terminal, the second input terminal, the third input terminal and the fourth input terminal of the sensitive amplifier array form the first group of input terminals of the sensitive amplifier array. The output terminal of the first sensitive amplifier is a first output terminal of the sensitive amplifier array, the output terminal of the second sensitive amplifier is a second output terminal of the sensitive amplifier array, the output terminal of the third sensitive amplifier is a third output terminal of the sensitive amplifier array, the output terminal of the fourth sensitive amplifier is a fourth output terminal of the sensitive amplifier, and the first output terminal, the second output terminal, the third output terminal and the fourth output terminal of the sensitive amplifier array form the first group of output terminals of the sensitive amplifier array. Each of the four sensitive amplifiers includes a thirteenth PMOS transistor, a fourteenth PMOS transistor, a fifteenth PMOS transistor, a sixteenth PMOS transistor, a thirteenth NMOS transistor, a fourteenth NMOS transistor, a fifteenth NMOS transistor, a sixteenth NMOS transistor and a seventeenth NMOS transistor, wherein a supply voltage is accessed to a source of the thirteenth PMOS transistor, a source of the fourteenth PMOS transistor, a source of the fifteenth PMOS transistor and a source of the sixteenth PMOS transistor; a gate of the thirteenth PMOS transistor, a gate of the sixteenth PMOS transistor and a gate of the seventeenth NMOS transistor are connected to a connecting terminal which is the second input terminal of the four sensitive amplifiers; a drain of the thirteenth PMOS transistor, a drain of the fourteenth PMOS transistor, a gate of the fifteenth PMOS transistor, a drain of the thirteenth NMOS transistor and a gate of the fourteenth NMOS transistor are connected to a connecting terminal which is the output terminal of the four sensitive amplifiers; a drain of the fifteenth PMOS transistor, a drain of the sixteenth PMOS transistor, a gate of the fourteenth PMOS transistor, a gate of the thirteenth NMOS transistor and a drain of the fourteenth NMOS transistor are connected; a drain of the fourteenth NMOS transistor and a source of the thirteenth NMOS transistor are connected; a drain of the sixteenth NMOS transistor and a source of the fourteenth NMOS transistor are connected; a gate of the fifteenth NMOS transistor is the first input terminal of the four sensitive amplifiers; a gate of the sixteenth NMOS transistor is the third input terminal of the four sensitive amplifiers; a source of the fifteenth NMOS transistor, a source of the sixteenth NMOS transistor and a drain of the seventeenth NMOS transistor are connected; and a source of the seventeenth NMOS transistor is grounded.

The key row includes four key cells. Each of the four key cells has an input terminal, a control terminal and two input-output terminals. The two input-output terminals are referred to as a first input-output terminal and a second input-output terminal, respectively. The input terminals of the four key cells are connected to a connecting terminal which is the first input terminal of the key row. The control terminals of the four key cells are connected to a connecting terminal which is the control terminal of the key row. The first input-output terminal of a first key cell is a first input-output terminal of the key row, the first input-output terminal of a second key cell is a second input-output terminal of the key row, the first input-output terminal of a third key cell is a third input-output terminal of the key row, the first input-output terminal of a fourth key cell is a fourth input-output terminal of the key row, and the first input-output terminal, the second input-output terminal, the third input-output terminal and the fourth input-output terminal of the key row form the first group of input-output terminals of the key row. The second input-output terminal of the first key cell is a fifth input-output terminal of the key row, the second input-output terminal of the second key cell is a sixth input-output terminal of the key row, the second input-output terminal of the third key cell is a seventh input-output terminal of the key row, the second input-output terminal of the fourth key cell is an eighth input-output terminal of the key row, and the fifth input-output terminal, the sixth input-output terminal, the seventh input-output terminal and the eighth input-output terminal of the key row form the second group of input-output terminals of the key row. Each of the four key cells includes a seventeenth PMOS transistor, an eighteenth PMOS transistor, an eighteenth NMOS transistor, a nineteenth NMOS transistor, a twentieth NMOS transistor and a twenty-first NMOS transistor. A source of the seventeenth PMOS transistor and a source of the eighteenth PMOS transistor are connected to a connecting terminal which is the control terminal of the key cell; a gate of the nineteenth NMOS transistor and a gate of the nineteenth NMOS transistor are connected to a connecting terminal which is the input terminal of the key row; a gate of the seventeenth PMOS transistor, a gate of the twentieth NMOS transistor, a drain of the eighteenth PMOS transistor, a drain of the twenty-first NMOS transistor and a source of the nineteenth NMOS transistor are connected; a gate of the eighteenth PMOS transistor, a gate of the twenty-first NMOS transistor, a drain of the seventeenth PMOS transistor, a drain of the twentieth NMOS transistor and a source of the eighteenth NMOS transistor are connected; a drain of the eighteenth NMOS transistor is the first input-output terminal of the key cell; a drain of the nineteenth NMOS transistor is the second input-output terminal of the key cell; and a source of the twentieth NMOS transistor and a source of the twenty-first NMOS transistor are grounded.

The on-off control array includes three on-off control cells. Each of the three on-off control cells has a control terminal, a first group of input terminals, a second group of input terminals, a first group of output terminals and a second group of output terminals. The control terminal of a first on-off control cell is the first control terminal of the on-off control array, the control terminal of a second on-off control cell is the second control terminal of the on-off control array, the control terminal of a third control cell is the third control terminal of the on-off control array, the first group of input terminals of the first on-off control cell is the first group of input terminals of the on-off control array, the second group of input terminals of the first on-off control cell is the second group of input terminals of the on-off control array, the first group of output terminals of the first on-off control cell are respectively connected to the first group of input terminals of the second on-off control cell and the first group of input terminals of the third on-off control cell at connecting terminals which are the first group of input-output terminals of the on-off control array. The second group of output terminals of the first on-off control cell are respectively connected to the second group of input terminals of the second on-off control cell and the second group of input terminals of the third on-off control cell at connecting terminals which are the second group of input-output terminals of the on-off control array. The first group of output terminals of the second on-off control cell is the first group of output terminals of the on-off control array, the second group of output terminals of the second on-off control cell is the second group of output terminals of the on-off control array, the first group of output terminals of the third on-off control cell is the third group of output terminals of the on-off control array, and the second group of output terminals of the third on-off control cell is the fourth group of output terminals of the on-off control array. Each of the three on-off control cells includes eight on-off control circuits. Each of the eight on-off control circuits has a control terminal, an input terminal and an output terminal. The control terminals of the eight on-off control circuits are connected to a connecting terminal which is the control terminal of the three on-off control cells; the input terminal of a first on-off control circuit is a first input terminal of the three on-off control cells, the input terminal of a second on-off control circuit is a second input terminal of the three on-off control cells, the input terminal of a third on-off control circuit is a third input terminal of the three on-off control cells, the input terminal of a fourth on-off control circuit is a fourth input terminal of the three on-off control cells, and the first input terminal, the second input terminal, the third input terminal and the fourth input terminal of the three on-off control cells form the first group of input terminals of the three on-off control cells. The input terminal of a fifth on-off control circuit is a fifth input terminal of the three on-off control cells, the input terminal of a sixth on-off control circuit is a sixth input terminal of the three on-off control cells, the input terminal of a seventh on-off control circuit is a seventh input terminal of the three on-off control cells, the input terminal of an eighth on-off control circuit is an eighth input terminal of the three on-off control cells, and the fifth input terminal, the sixth input terminal, the seventh input terminal and the eighth input terminal of the three on-off control cells form the second group of input terminals of the three on-off control cells. The output terminal of the first on-off control circuit is a first output terminal of the three on-off control cells, the output terminal of the second on-off control circuit is a second output terminal of the three on-off control cells, the output terminal of the third on-off control circuit is a third output terminal of the three on-off control cells. The output terminal of the fourth on-off control circuit is a fourth output terminal of the three on-off control cells, and the first output terminal, the second output terminal, the third output terminal and the fourth output terminal of the three on-off control cells form the first group of output terminals of the three on-off control cells; and the output terminal of the fifth on-off control circuit is a fifth output terminal of the three on-off control cells, the output terminal of the sixth on-off control cell is a sixth output terminal of the three on-off control cells, the output terminal of the seventh on-off control cell is a seventh output terminal of the three on-off control cells, the output terminal of the eighth on-off control cell is an eighth output terminal of the three on-off control cells, and the fifth output terminal, the sixth output terminal, the seventh output terminal and the eighth output terminal of the three on-off control cells form the second group of output terminals of the three on-off control cells. Each of the eight on-off control circuits includes a nineteenth PMOS transistor, a twentieth PMOS transistor, a twenty-second NMOS transistor and a twenty-third NMOS transistor, wherein a drain of the nineteenth PMOS transistor and a drain of the twenty-second NMOS transistor are connected to a connecting terminal which is the input terminal of the on-off control circuit; a source of the nineteenth PMOS transistor and a source of the twenty-second NMOS transistor are connected to a connecting terminal which is the output terminal of the on-off control circuit; a gate of the nineteenth PMOS transistor, a gate of the twenty-third NMOS transistor and a gate of the twentieth PMOS transistor are connected. A supply voltage is accessed to a source of the twentieth PMOS transistor; a drain of the twentieth PMOS transistor, a drain of the twenty-third NMOS transistor and a gate of the twenty-second NMOS transistor are connected to a connecting terminal which is the control terminal of the on-off control circuit; and a source of the twenty-third NMOS transistor is grounded.

The secure storage array includes sixteen secure storage cells which are distributed in four rows and four columns. Each of the sixteen secure storage cells has a first input terminal, a second input terminal, a third input terminal, a fourth input terminal, a fifth input terminal, a first input-output terminal and a second input-output terminal. The first input terminals of the four secure storage cells in a first row are connected to a connecting terminal which is a first input terminal of the secure storage array; the first input terminals of the four secure storage cells in a second row are connected to a connecting terminal which is a second input terminal of the secure storage array; the first input terminals of the four storage cells in a third row are connected to a connecting terminal which is a third input terminal of the secure storage array; the first input terminals of the four secure storage cells in a fourth row are connected to a connecting terminal which is a fourth input terminal of the cell storage array; and the first input terminal, the second input terminal, the third input terminal and the fourth input terminal of the secure storage array form the first group of input terminals of the secure storage array. The second input terminals of the four secure storage cells in the first row are connected to a connecting terminal which is a fifth input terminal of the secure storage array; the second input terminals of the four secure storage cells in the second row are connected to a connecting terminal which is a sixth input terminal of the secure storage array; the second input terminals of the four secure storage cells in the third row are connected to a connecting terminal which is a seventh input terminal of the secure storage cell; the second input terminals of the four secure storage cells in the fourth row are connected to a connecting terminal which is an eighth input terminal of the secure storage array; and the fifth input terminal, the sixth input terminal, the seventh input terminal and the eighth input terminal of the secure storage array form the second group of input terminals of the secure storage array. The third input terminals of the four secure storage cells in the first row are connected to a connecting terminal which is a ninth input terminal of the secure storage array; the third input terminals of the four secure storage cells in the second row are connected to a connecting terminal which is a tenth input terminal of the secure storage array; the third input terminals of the four secure storage cells in the third row are connected to a connecting terminal which is an eleventh input terminal of the secure storage array; the third input terminals of the four secure storage cells in the fourth row are connected to a connecting terminal which is a twelfth input terminal of the secure storage array; and the ninth input terminal, the tenth input terminal, the eleventh input terminal and the twelfth input terminal of the secure storage array form the third group of input terminals of the secure storage array. The fourth input terminals of the four secure storage cells in a first column are connected to a connecting terminal which is a thirteenth input terminal of the secure storage array; the fourth input terminals of the four secure storage cells of in a second column are connected, and a connecting terminal is a fourteenth input terminal of the secure storage array; the fourth input terminals of the four secure storage cells in a third column are connected to a connecting terminal which is a fifteenth input terminal of the secure storge array; the fourth input terminals of the four secure storage cells of in a fourth column are connected to a connecting terminal which is a sixteenth input terminal of the secure storage array; and the thirteenth input terminal, the fourteenth input terminal, the fifteenth input terminal and the sixteenth input terminal of the secure storage array from the fourth group of input terminals of the secure storage array. The fifth input terminals of the fourth storage cells in the first column are connected to a connecting terminal which is a seventeenth input terminal of the secure storage cell; the fifth input terminals of the four secure storage cells in the second column are connected to a connecting terminal which is an eighteenth input terminal of the secure storage array; the fifth input terminals of the four secure storage cells of in the third column are connected to a connecting terminal which is a nineteenth input terminal of the secure storage array; the fifth input terminals of the four secure storage cells in the fourth column are connected to a connecting terminal which is a twentieth input terminal of the secure storage array; and the seventeenth input terminal, the eighteenth input terminal, the nineteenth input terminal and the twentieth input terminal of the secure storage array form the fifth group of input terminals of the secure storage array. The first input-output terminals of the four secure storage cells in the first column are connected to a connecting terminal which is a first input-output terminal of the secure storage array; the first input-output terminals of the four secure storage cells in the second column are connected to a connecting terminal which is a second input-output terminal of the secure storage array; the first input-output terminals of the four secure storage cells in the third column are connected to a connecting terminal which is a third input-output terminal of the secure storage array; the first input-output terminals of the four secure storage cells in the fourth column are connected to a connecting terminal which is a fourth input-output terminal of the secure storage array; and the first input-output terminal, the second input-output terminal, the third input-output terminal and the fourth input-output terminal of the secure storage array form the first group of input-output terminals of the secure storage array. The second input-output terminals of the four secure storage cells in the first column are connected to a connecting terminal which is a fifth input-output terminal of the secure storage array; the second input-output terminals of the four secure storage cells in the second column are connected to a connecting terminal which is a sixth input-output terminal of the secure storage array; the second input-output terminals of the four secure storage cells in the third column are connected to a connecting terminal which is a seventh input-output terminal of the secure storage array; the second input-output terminals of the four secure storage cells in the fourth column are connected to a connecting terminal which is an eighth input-output terminal of the secure storage array; and the fifth input-output terminal, the sixth input-output terminal, the seventh input-output terminal and the eighth input-output terminal of the secure storage cell form the second group of input-output terminals of the secure storage array. The third input-output terminals of the four secure storage cells in the first column are connected to a connecting terminal which is a ninth input-output terminal of the secure storage array; the third input-output terminals of the four secure storage cells in the second column are connected to a connecting terminal which is a tenth input-output terminal of the secure storage array; the third input-output terminals of the four secure storage cells in the third column are connected to a connecting terminal which is an eleventh input-output terminal of the secure storage array; the third input-output terminals of the four secure storage cells in the fourth column are connected to a connecting terminal which is a twelfth input-output terminal of the secure storage array; and the ninth input-output terminal, the tenth input-output terminal, the eleventh input-output terminal and the twelfth input-output terminal of the secure storage array form the third group of input terminals of the secure storage array. Each of the sixteen secure storage cells includes a twenty-first PMOS transistor, a twenty-second PMOS transistor, a twenty-third PMOS transistor, a twenty-fourth PMOS transistor, a twenty-fifth PMOS transistor, a twenty-sixth PMOS transistor, a twenty-fourth NMOS transistor, a twenty-fifth NMOS transistor, a twenty-sixth NMOS transistor, a twenty-seventh NMOS transistor, a twenty-eighth NMOS transistor, a twenty-ninth NMOS transistor and a first capacitor, wherein a source of the twenty-first PMOS transistor, a source of the twenty-second PMOS transistor, a source of the twenty-fifth PMOS transistor and a source of the twenty-sixth PMOS transistor are connected to a connecting terminal which is the first input terminal of the secure storage cell; a gate of the twenty-first PMOS transistor, a gate of the twenty-sixth NMOS transistor, a drain of the twenty-second PMOS transistor, a source of the twenty-seventh NMOS transistor, a source of the twenty-fifth NMOS transistor and a source of the twenty-fourth PMOS transistor are connected; a gate of the twenty-second PMOS transistor, a gate of the twenty-seventh NMOS transistor, a drain of the twenty-first PMOS transistor, a source of the twenty-sixth NMOS transistor, a source of the twenty-fourth NMOS transistor and a source of the twenty-third PMOS transistor are connected; a gate of the twenty-fourth NMOS transistor and a gate of the twenty-fifth PMOS transistor are connected to a connecting terminal which is the second input terminal of the secure storage cell; a drain of the twenty-fourth NMOS transistor is the first input-output terminal of the secure storage cell; a drain of the twenty-fifth PMOS transistor is the second input-output terminal of the secure storage cell; a gate of the twenty-third PMOS transistor, a source of the twenty-eighth NMOS transistor and a drain of the twenty-fifth PMOS transistor are connected; a gate of the twenty-fourth PMOS transistor, a source of the twenty-ninth NMOS transistor and a drain of the twenty-sixth PMOS transistor are connected; a drain of the twenty-eighth NMOS transistor is the fourth input terminal of the secure storage cell; a drain of the twenty-ninth NMOS transistor is the fifth input terminal of the secure storage cell; a gate of the twenty-eighth NMOS transistor, a gate of the twenty-ninth NMOS transistor, a gate of the twenty-fifth PMOS transistor and a gate of the twenty-sixth PMOS transistor are connected to a connecting terminal which is the third input terminal of the secure storage cell; a drain of the twenty-third PMOS transistor, a drain of the twenty-fourth PMOS transistor and one terminal of the first capacitor are connected to a connecting terminal which is the third input-output terminal of the secure storage cell; and a drain of the twenty-sixth NMOS transistor, a drain of the twenty-seventh NMOS transistor and the other terminal of the first capacitor are grounded.

Compared with the prior art, the invention has the following beneficial effects: the low-overhead encryption and decryption circuit based on hardware multiplexing is formed by the secure storage array, the timing control module, the key row, the sensitive amplifier array, the inverter array, the on-off control array, the write circuit and the two refresh circuits; the secure storage array is configured to store data to be encrypted, XOR data and decrypted data and encrypt and decrypt data, and is realized based on the hardware multiplexing technique, thereby reducing hardware overheads; the key row, when needed to generate keys, generates the keys under the control of the timing control circuit and when not used, is controlled by the timing control circuit to be powered off and reset, and the key row adopts a dynamic key generation technique and avoids the unsecure behavior of key storage, thereby having high security. Thus, the low-overhead encryption and decryption circuit based on hardware multiplexing provided by the invention has low hardware overheads and high security.

### BRIEF DESCRIPTION OF THE DRAWINGS

FIG. 1 is a block diagram of an encryption and decryption circuit according to the invention;

FIG. 2 is a block diagram of a write circuit of the encryption and decryption circuit according to the invention;

FIG. 3 is a circuit diagram of a first write cell of the encryption and decryption circuit according to the invention;

FIG. 4 is a circuit diagram of a second write cell of the encryption and decryption circuit according to the invention;

FIG. 5 is a block diagram of a first refresh circuit of the encryption and decryption circuit according to the invention;

FIG. 6 is a circuit diagram of a first refresh cell of the encryption and decryption circuit according to the invention;

FIG. 7 is a block diagram of a second refresh circuit of the encryption and decryption circuit according to the invention;

FIG. 8 is a circuit diagram of a second refresh cell of the encryption and decryption circuit according to the invention;

FIG. 9 is a block diagram of an inverter array of the encryption and decryption circuit according to the invention;

FIG. 10 is a circuit diagram of an inverter of the encryption and decryption circuit according to the invention;

FIG. 11 is a block diagram of a sensitive amplifier array of the encryption and decryption circuit according to the invention;

FIG. 12 is a circuit diagram of a sensitive amplifier of the encryption and decryption circuit according to the invention;

FIG. 13 is a block diagram of a key row of the encryption and decryption circuit according to the invention;

FIG. 14 is a circuit diagram of a key cell of the encryption and decryption circuit according to the invention;

FIG. 15 is a block diagram of an on-off control array of the encryption and decryption circuit according to the invention;

FIG. 16 is a block diagram of an on-off control circuit of the encryption and decryption circuit according to the invention;

FIG. 17 is a circuit diagram of an on-off control cell of the encryption and decryption circuit according to the invention;

FIG. 18 is a block diagram of a secure storage array of the encryption and decryption circuit according to the invention;

FIG. 19 is a circuit diagram of a secure storage cell of the encryption and decryption circuit according to the invention;

FIG. 20 is a functional simulation oscillogram of the encryption and decryption circuit according to the invention.

### DESCRIPTION OF THE EMBODIMENTS

The invention is described in further detail below in conjunction with accompanying drawings and embodiments.

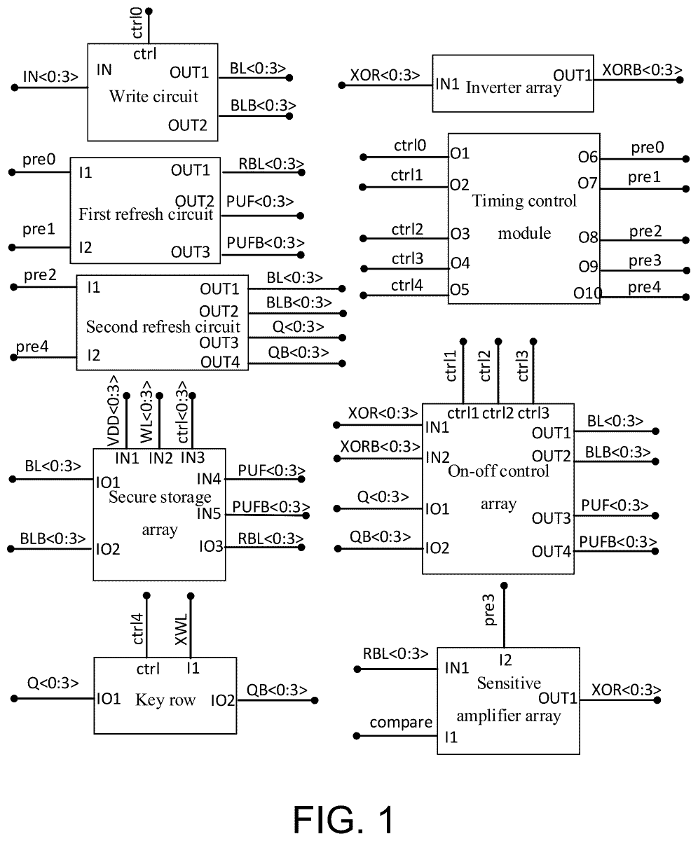

Embodiment 1: As shown in FIG. 1, a low-overhead encryption and decryption circuit based on hardware multiplexing includes a secure storage array, a timing control module, a key row, a sensitive amplifier array, an inverter array, an on-off control array, a write circuit and two refresh circuits. The two refresh circuits are referred to as a first refresh circuit and a second refresh circuits, respectively. The secure storage array is realized based on a hardware multiplexing technique to reduce overheads of hardware resources. When encryption is needed, first, the timing control module controls the second refresh circuit to output a reset signal to refresh the secure storage array to reset the state of the secure storage array; then, when data to be encrypted are transmitted to the write circuit, the write circuit, under the control of the timing control module, converts the data to be encrypted into two types of data with opposite phases and outputs the two types of data with opposite phases to the secure storage array, and the secure storage array stores the two types of data with opposite phases, output thereto by the write circuit; then, the timing control module, on one hand, controls the first refresh circuit to output a pre-charge signal to pre-charge the secure storage array and on the other and, controls the second refresh circuit to output a reset signal to refresh the key row to reset the state of the key row; then, the timing control module controls the key row to generate a pair of keys with opposite phases and transmits the pair of keys with opposite phases to the on-off control array; the on-off control array transmits the pair of keys, transmitted thereto by the key row, to the secure storage array; the secure storage array performs an XOR operation on the pair of keys currently transmitted thereto by the key row and the two types of data with opposite phases stored therein to obtain a one-bit XOR value and transmits the XOR value to the sensitive amplifier array; the sensitive amplifier array, under the control of the timing control module, shapes the XOR value output thereto to obtain a shaped XOR value and transmits the shaped XOR value to the inverter array; the inverter array performs phase inversion on the shaped XOR value to obtain an XOR value with an opposite phase and transmits the XOR value with the opposite phase to the on-off control array; the on-off control array transmits the shaped XOR value transmitted thereto by the sensitive amplifier array and the XOR value with the opposite phase reversely transmitted thereto by the inverter array to the secure storage array; and the secure storage array stores the shaped XOR value and the XOR value with the opposite phase as encrypted data, such that encryption is realized. When the encrypted data stored in the secure storage array need to be decrypted, first, the timing control module, on one hand, controls the first refresh circuit to output a pre-charge signal to pre-charge the secure storage array and on the other hand, controls the second refresh circuit to output a reset signal to refresh the key row to reset the state of the key row; then, the timing control module controls the key row to generate a pair of keys with opposite phases and transmits the pair of keys with opposite phases to the on-off control array; the on-off control array transmits the pair of keys transmitted thereto by the key row to the secure storage array; the secure storage array performs an XOR operation on the pair of keys received currently and the encrypted data stored therein to obtain a one-bit initial value and transmits the one-bit initial value to the sensitive amplifier array; the sensitive amplifier array, under the control of the timing control module, shapes the initial value to obtain a shaped initial value and transmits the shaped initial value to the inverter array; the inverter array performs phase inversion on the shaped initial value to obtain an initial value with an opposite phase and transmits the initial value with the opposite phase to the on-off control array; the on-off control array transmits the one-bit initial value output thereto by the sensitive amplifier array and the initial value with the opposite phase output thereto by the inverter array to the secure storage array; and the secure storage array stores the one-bit initial value and the initial value with the opposite phase, and at this moment, the pair of data stored in the secure storage array is the same as the pair of data input by the write circuit during encryption, such that data decryption is realized.

In this embodiment of the invention, the secure storage array is configured to store data to be encrypted, XOR data and decrypted data and encrypt and decrypt data, and is realized based on the hardware multiplexing technique, thereby reducing hardware overheads; the key row, when needed to generate keys, generates the keys under the control of the timing control circuit and when not used, is controlled by the timing control circuit to be powered off and reset, and the key row adopts a dynamic key generation technique and avoids the unsecure behavior of key storage, thereby having high security. Thus, the low-overhead encryption and decryption circuit based on hardware multiplexing has low hardware overheads and high security.

Embodiment 2: This embodiment is basically the same as Embodiment 1 and is different from Embodiment 1 in the following aspect: in this embodiment, the write circuit has a group of input terminals, two groups of output terminals and a control terminal, wherein four-bit binary data are input to the group of input terminals, each group of output terminals is configured to output four-bit binary data, the group of input terminals is referred to as a first group of input terminals, the two groups of output terminals are referred to as a first group of output terminals and a second group of output terminals, respectively, and the control terminal is referred to as a first control terminal. The first refresh circuit has two input terminals and three groups of output terminals, wherein the two input terminals are referred to as a first input terminal and a second input terminal respectively, each group of output terminals is configured to output four-bit binary data, and the three groups of output terminals are referred to as a first group of output terminals, a second group of output terminals and a third group of output terminals, respectively. The second refresh circuit has two input terminals and four groups of output terminals, wherein the two input terminals are referred to as a first input terminal and a second input terminal, respectively, each group of output terminals is configured to output four-bit binary data, the four groups of output terminals are referred to as a first group of output terminals, a second group of second output terminals, a third group of output terminals and a fourth group of output terminals, respectively. The sensitive amplifier array has two input terminals, a group of input terminals and a group of output terminals, wherein the two input terminals are referred to as a first input terminal and a second terminal, respectively, four-bit binary data are input to the group of input terminals, the group of input terminals is referred to as a first group of input terminal, and the group of output terminals is configured to output four-bit binary data and referred to as a first group of output terminals. The secure storage array has five groups of input terminals and three groups of input-output terminals, wherein four-bit binary data are input to each group of input terminals, each group of input-output terminals is configured to output four-bit binary data or allow four-bit binary data to be input thereto, the five groups of input terminals are referred to as a first group of input terminals, a second group of input terminals, a third group of input terminals, a fourth group of input terminals and a fifth group of input terminals, respectively, and the three groups of input-output terminals are referred to as a first group of input-output terminals, a second group of input-output terminals and a third group of input-output terminals, respectively. The key row has an input terminal, two groups of input-output terminals and a control terminal, wherein the input terminal is referred to as a first input terminal, each group of input-output terminals is configured to output four-bit binary data or allow four-bit binary data to be input thereto, the two groups of input-output terminals are referred to as a first group of input-output terminals and a second group of input-output terminals, respectively, and the control terminal is referred to as a first control terminal. The inverter array has a group of input terminals and a group of output terminals, wherein four-bit binary data are input to the group of input terminals, the group of output terminals is configured to output four-bit binary data, the group of input terminals is referred to as a first group of input terminals, and the group of output terminals is referred to as a first group of output terminals. The timing control module has ten output terminals, wherein the ten output terminals are referred to as a first output terminal, a second output terminal, a third output terminal, a fourth output terminal, a fifth output terminal, a sixth output terminal, a seventh output terminal, an eighth output terminal, a ninth output terminal and a tenth output terminal, respectively. The timing control module is configured to control the secure storage array, the key row, the sensitive amplifier array, the inverter array, the on-off control array, the write circuit and the two refresh circuits to work coordinately. The first output terminal, the second output terminal, the third output terminal, the fourth terminal and the fifth output terminal of the timing control module are configured to output control signals, respectively. The sixth output terminal, the seventh output terminal, the eighth output terminal, the ninth output terminal and the tenth output terminal of the timing control module are configured to output refresh signals, respectively. The control signal output by the first output terminal of the timing control module is denoted as ctrl0, the control signal output by the second output terminal of the timing control module is denoted as ctrl1, the control signal output by the third output terminal of the timing control module is denoted as ctrl2, the control signal output by the fourth output terminal of the timing control module is denoted as ctrl3, the control signal output by the fifth output terminal of the timing control module is denoted as ctrl4, the refresh signal output by the sixth output terminal of the timing control module is denoted as pre0, the refresh signal output by the seventh output terminal of the timing control module is denoted as pre1, refresh signal output by the eighth output terminal of the timing control module is denoted as pre2, the refresh signal output by the ninth output terminal of the timing control module is denoted as pre3, and the refresh signal output by the tenth output terminal of the timing control module is denoted as pre4. The on-off control array has two groups of input terminals, four groups of output terminals, two groups of input-output terminals and three control terminals, wherein four-bit binary data are input to each group of input terminals, each group of output terminals is configured to output four-bit binary data, each group of input-output terminals is configured to output four-bit binary data or allow four-bit binary data to be input thereto, the two groups of input terminals are referred to as a first group of input terminals and a second group of input terminals, respectively, the four groups of output terminals are referred to as a first group of output terminals, a second group of output terminals, a third group of output terminals and a fourth group of output terminals, respectively, the two groups of input-output terminals are referred to as a first group of input-output terminals and a second group of input-output terminals, respectively, and the three control terminals are referred to as a first control terminal, a second control terminal and a third control terminal, respectively. Four-bit data to be encrypted are denoted as IN<0:3>, the four-bit data IN<0:3> to be encrypted are input to the first group of input terminals of the write circuit, the first group of output terminals of the write circuit is configured to output one of two types of data with opposite phases, the second group of output terminals of the write circuit is configured to output the other one of the two types of data with opposite phases, the first group of output terminals of the write circuit is connected to the first group of input-output terminals of the secure storage array, the first group of output terminals of the second refresh circuit and the first group of output terminals of the on-off control array, the second group of output terminals of the write circuit is connected to the second group of input-output terminals of the secure storage array, the second group of output terminals of the second refresh circuit and the second group of output terminals of the on-off control array, the first control terminal of the write circuit is connected to the first output terminal of the timing control module, the first input terminal of the first refresh circuit is connected to the sixth output terminal of the timing control module, the second input terminal of the first refresh circuit is connected to the seventh output terminal of the timing control module, the first input terminal of the first refresh circuit is connected to the sixth output terminal of the timing control module, the second input terminal of the first refresh circuit is connected to the seventh output terminal of the timing control module, the first group of output terminals of the first refresh circuit is connected to the third group of input-output terminals of the secure storage array and the first group of input terminals of the sensitive amplifier array, the second group of output terminals of the first refresh circuit is connected to the fourth group of input terminals of the secure storage array and the third group of output terminals of the on-off control array, the second group of output terminals of the first refresh circuit is configured to output a pre-charge signal, which is four-bit binary data, the third group of output terminals of the first refresh circuit is connected to the fifth group of input terminals of the secure storage array and the fourth group of output terminals of the on-off control array, the third group of output terminals of the first refresh circuit is configured to output a pre-charge signal, which is four-bit binary data, the first input terminal of the second refresh circuit is connected to the eighth output terminal of the timing control module, the second input terminal of the second refresh circuit is connected to the tenth output terminal of the timing control module, the third group of output terminals of the second refresh circuit is connected to the first group of input-output terminals of the key row and the first group of input-output terminals of the on-off control array, the third group of output terminals of the second refresh circuit is configured to output a reset signal, which is four-bit binary data, the fourth group of output terminals of the second refresh circuit is connected to the second group of input-output terminals of the key row and the second group of input-output terminals of the on-off control array, the fourth group of output terminals of the second refresh circuit is configured to output a reset signal, which is four-bit binary data, an external threshold voltage compare (set according to actual usage requirements) is input to the first input terminal of the sensitive amplifier array, the first group of output terminals of the sensitive amplifier array is configured to output a shaped XOR value, which is four-bit binary data, the second input terminal of the sensitive amplifier array is connected to the ninth output terminal of the timing control module, the first group of output terminals of the sensitive amplifier array is connected to the first group of input terminals of the inverter array and the first group of input terminals of the on-off control array, a four-bit voltage signal VDD<0:3> is input to the first group of input terminals of the secure storage array, a four-bit word line control signal WL<0:3> is input to the second group of input terminals of the secure storage array, and a four-bit on-off control signal ctrl<0:3> is input to the third group of input terminals of the secure storage array; the four-bit voltage signal VDD<0:3> is configured to control power-on and power-off of the secure storage array, the four-bit word line control signal WL<0:3> is configured to control the secure storage array to store or not store data BL<0:3> input to the first input-output terminal thereof and data BLB<0:3> input to the second input-output terminal thereof, the four-bit on-off control signal ctrl<0:3> is configured to control the secure storage array to store or not store data input to the fourth input terminal thereof and data input to the fifth input terminal thereof, the first control terminal of the key row is connected to the fifth output terminal of the timing control module, a word line control signal XWL is input to the first input terminal of the key row, and the word line control signal XWL is configured to control transmission of keys of the key row; and the first group of output terminals of the inverter array is configured to output a shaped XOR value subjected to phase inversion, the first group of output terminals of the inverter array is connected to first group of input terminals of the on-off control array, the first control terminal of the on-off control array is connected to the second output terminal of the timing control module, the second control terminal of the on-off control array is connected to the third output terminal of the timing control module, and the third control terminal of the on-off control array is connected the fourth output terminal of the timing control module.

In this embodiment, when encryption is needed, first, the eighth output terminal of the timing control module outputs the refresh signal pre2 to control the first group of output terminals and the second group of output terminals of the second refresh circuit to output a reset signal to refresh the first group of input-output terminals and the second group of input-output terminals of the secure storage array to reset the state of the secure storage array; then, when the data IN<0:3> to be encrypted are transmitted to the write circuit, the write circuit, under the control of the control signal ctrl0 output by the first output terminal of the timing control module, converts the data IN<0:3> to be encrypted into two types of data with opposite phases and outputs the two types of data to the first group of input-output terminals and the second group of input-output terminals of the secure storage array in one-to-one correspondence by means of the first group of output terminals and the second group of output terminals thereof; the secure storage array stores the data input to the first group of input-output terminals thereof and the data input to the second group of input-output terminals thereof; then, the timing control module outputs the refresh signal pre0 by means of the sixth output terminal and outputs the refresh signal pre4 by means of the tenth output terminal, at this moment, the first refresh circuit outputs a pre-charge signal by means of the first group of output terminals thereof to pre-charge the third group of input-output terminals of the secure storage array, and the second refresh circuit outputs a reset signal by means of the third group of output terminals and the fourth group of output terminals thereof to refresh the first group of input-output terminals and the second group of input-output terminals of the key row to reset the state of the key row; then, the fifth output terminal of the timing control module outputs the control signal ctrl4 to control the key row to generate a pair of keys with opposite phases and transmits the pair of keys with opposite phases to the first group of input-output terminals and the second group of input-output terminals of the on-off control array in one-to-one correspondence by means of the first group of input-output terminals and the second group of input-output terminals thereof; the third output terminal of the timing control array outputs the control signal ctrl2 to control the on-off control array, and the on-off control array transmits the pair of keys, transmitted thereto by the key row, to the fourth group of input-output terminals and the fifth group of input-output terminals of the secure storage array by means of the third group of output terminals and the fourth group of output terminals thereof; the secure storage array performs an XOR operation on the pair of keys received currently and the two types of data with opposite phases stored therein to obtain a one-bit XOR value, which is transmitted to the first group of input terminals of the sensitive amplifier array by means of the third group of input-output terminals of the secure storage array; the ninth output terminal of the timing control module outputs the refresh signal pre3, and the sensitive amplifier array, under the control of the refresh signal pre3, shapes the one-bit XOR value output thereto to obtain a shaped XOR value, which is transmitted to the first group of input terminals of the inverter array by means of the first group of output terminals of the sensitive amplifier array; the inverter array performs phase inversion on the shaped XOR value to obtain an XOR value with an opposite phase, which is transmitted to the second group of input terminals of the on-off control array by means of the first group of output terminals of the inverter array; the on-off control array transmits the shaped XOR value transmitted thereto by the sensitive amplifier array and the XOR value with the opposite phase reversely transmitted thereto by the inverter array to the first group of input-output terminals and the second group of input-output terminals of the secure storage array in one-to-one correspondence by means of the first group of output terminals and the second group of output terminals thereof; the secure storage array stores the shaped XOR value and the XOR value with the opposite phase as encrypted data, such that encryption is realized. When the encrypted data stored in the secure storage array need to be decrypted, first, the sixth output terminal of the timing control module outputs the refresh signal pre0 and the tenth output terminal of the timing control module outputs the refresh signal pre4, at this moment, the first refresh module, under the control of the refresh signal pre0, outputs a pre-charge signal to the third input-output terminal of the secure storage array by means of the first output terminal thereof to pre-charge the secure storage array, and the second refresh circuit, under the control of the refresh signal pre4, outputs a reset signal by means of the third group of output terminals and the fourth group of output terminals thereof to refresh the key row to reset the state of the first group of input-output terminals and the second group of input-output terminals of the key row; then, the fifth output terminal of the timing control module outputs the control signal ctrl4 to control the key row to generate a pair of keys with opposite phases and transmits the pair of keys to the first group of input-output terminals and the second group of input-output terminals of the on-off control array in one-to-one correspondence by means of the first group of input-output terminals and the second group of input-output terminals thereof; the third output terminal of the timing control module outputs the control signal ctrl2 to control the on-off control array to transmit the pair of keys, transmitted thereto by the key row, to the fourth group of input terminals and the fifth group of input terminals of the secure storage array by means of the third group of output terminals and the fourth group of output terminals thereof; the secure storage array performs an XOR operation on the pair of keys received currently and the encrypted data stored therein to obtain a one-bit initial value, which is transmitted to the first input terminal of the sensitive amplifier array; the sensitive amplifier array, under the control of the refresh signal pre3 output by the fourth output terminal of the timing control module, shapes the initial value to obtain a shaped initial value, which is transmitted to the first group of input terminals of the inverter array by means of the first group of output terminals of the sensitive amplifier array; the inverter array performs phase inversion on the shaped initial value to obtain an initial value with an opposite phase, which is transmitted to the second group of input terminals of the on-off control array by means of the first group of output terminals of the inverter array; the on-off control array transmits the one-bit initial value output thereto by the sensitive amplifier array and the initial value with the opposite phase output thereto by the inverter array to the first group of input-output terminals and the second group of input-output terminals of the secure storage array in one-to-one correspondence by means of the first group of output terminals and the second group of output terminals thereof; and the secure storage array stores the currently received one-bit initial value and the initial value with the opposite phase, and at this moment, the one-bit initial value and the initial value with the opposite phase stored in the secure storage array are the same as the pair of data with opposite phases stored in the secure storage array during encryption, such that data decryption is realized.

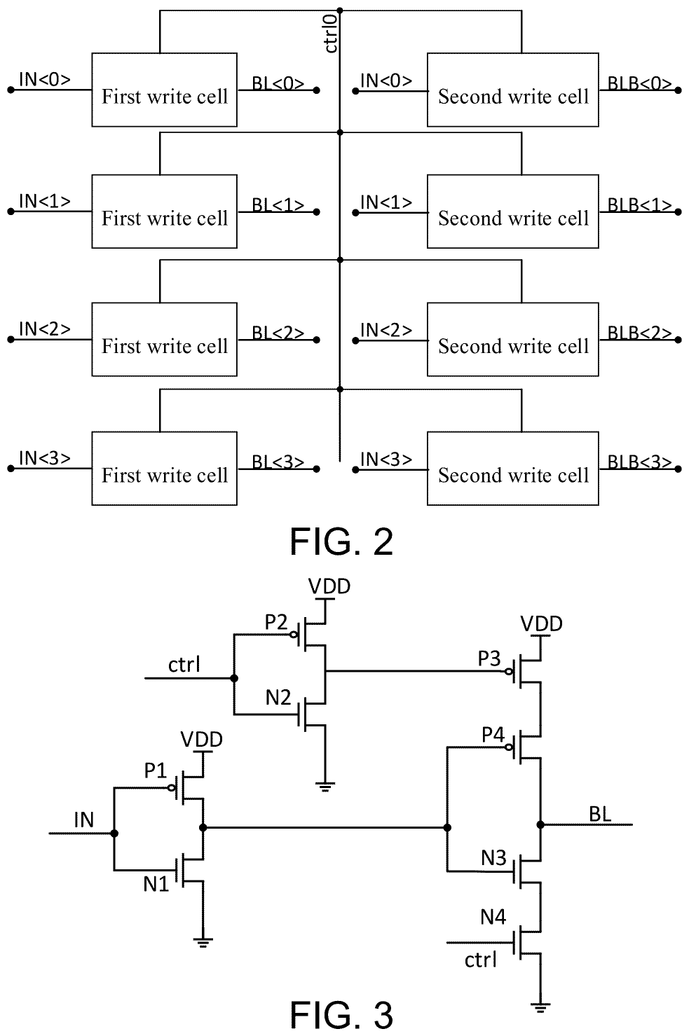

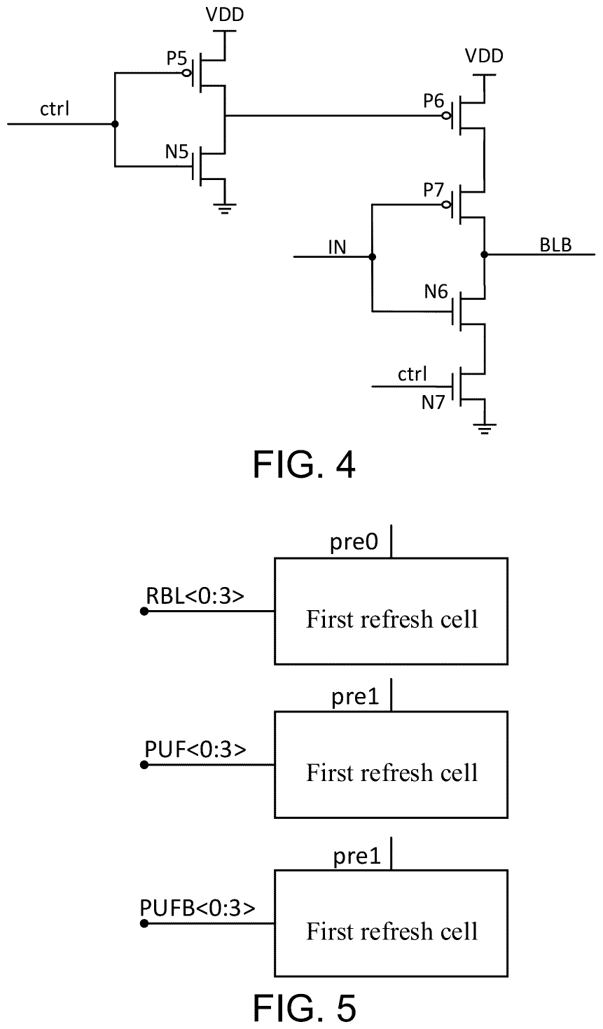

Embodiment 3: This embodiment is basically the same as Embodiment 2 and is different from Embodiment 2 in the following aspect: in this embodiment, as shown in FIGS. 2-4, the write circuit includes four first write cells and four second write cells, wherein each first write cell has an input terminal, an output terminal and a control terminal, each second write cell has an input terminal, an output terminal and a control terminal, the control terminals of the four first write cells and the control terminals of the four second write cells are connected and a connecting terminal is the first control terminal of the write circuit, the input terminal of a 1^{st} first write cell and the input terminal of a 1^{st} second write cell are connected and a connecting terminal is a first input terminal of the write circuit, the input terminal of a 2^{nd} first write cell and the input terminal of a 2^{nd} second write cell are connected and a connecting terminal is a second input terminal of the write circuit, the input terminal of a 3^{rd} first write cell and the input terminal of a 3^{rd} second write cell are connected and a connecting terminal is a third input terminal of the write circuit, the input terminal of a 4^{th} first write cell and the input terminal of a 4^{th} second write cell are connected and a connecting terminal is a fourth input terminal of the write circuit, and the first input terminal, the second input terminal, the third input terminal and the fourth input terminal of the write circuit form the first group of input terminals of the write circuit; the output terminal of the 1^{st} first write cell is a first output terminal of the write circuit, the output terminal of the 2^{nd} first write cell is a second output terminal of the write circuit, the output terminal of the 3^{rd} first write cell is a third output terminal of the write circuit, the output terminal of the 4^{th} first write cell is a fourth output terminal of the write circuit, and the first output terminal, the second output terminal, the third output terminal and the fourth output terminal of the write circuit form the first group of output terminals of the write circuit; the output terminal of the 1^{st} second write cell is a fifth output terminal of the write circuit, the output terminal of the 2^{nd} second write cell is a sixth output terminal of the write circuit, the output terminal of the 3^{rd} second write cell is a seventh output terminal of the write circuit, the output terminal of the 4^{th} second write cell is an eighth output terminal of the write circuit, and the fifth output terminal, the sixth output terminal, the seventh output terminal and the eighth output terminal of the write circuit form the second group of output terminals of the write circuit. Each first write cell includes a first PMOS transistor P1, a second PMOS transistor P2, a third PMOS transistor P3, a fourth PMOS transistor P4, a first NMOS transistor N1, a second NMOS transistor N2, a third NMOS transistor N3 and a fourth NMOS transistor N4, wherein a supply voltage is accessed to a source of the first PMOS transistor P1, a source of the second PMOS transistor P2 and a source of the third PMOS transistor P3; a gate of the first PMOS transistor P1 and a gate of the first NMOS transistor N1 are connected to a connecting terminal which is the input terminal of the first write cell; a drain of the first PMOS transistor P1, a drain of the first NMOS transistor N1, a gate of the fourth PMOS transistor P4 and a gate of the third NMOS transistor N3 are connected; a drain of the second PMOS transistor P2, a gate of the third PMOS transistor P3 and a drain of the second NMOS transistor N2 are connected; a gate of the second PMOS transistor P2, a gate of the second NMOS transistor N2 and a gate of the fourth NMOS transistor N4 are connected to a connecting terminal which is the control terminal of the first write cell; a drain of the third PMOS transistor P3 and a source of the fourth PMOS transistor P4 are connected; a drain of the fourth PMOS transistor P4 and a drain of the third NMOS transistor N3 are connected to a connecting terminal which is the output terminal of the first write cell; a source of the third NMOS transistor N3 and a drain of fourth NMOS transistor N4 are connected; and a source of the first NMOS transistor N1, a source of the second NMOS transistor N2 and a source of the fourth NMOS transistor N4 are grounded. Each second write cell includes a fifth PMOS transistor P5, a sixth PMOS transistor P6, a seventh PMOS transistor P7, a fifth NMOS transistor N5, a sixth NMOS transistor N6 and a seventh NMOS transistor N7, wherein a supply voltage is accessed to a source of the fifth PMOS transistor P5 and a source of the sixth PMOS transistor P6; a gate of the fifth PMOS transistor P5, a gate of the fifth NMOS transistor N5 and a gate of the seventh NMOS transistor N7 are connected to a connecting terminal which is the control terminal of the second write cell; a drain of the fifth PMOS transistor P5, a gate of the sixth PMOS transistor P6 and a drain of the fifth NMOS transistor N5 are connected; a drain of the sixth PMOS transistor P6 and a source of the seventh PMOS transistor P7 are connected; a gate of the sixth NMOS transistor N6 and a gate of the seventh PMOS transistor P7 are connected to a connecting terminal which is the input terminal of the second write circuit; a source of the sixth NMOS transistor N6 and a drain of the seventh PMOS transistor P7 are connected to a connecting terminal which is the output terminal of the second write circuit; a drain of the sixth NMOS transistor N6 and a drain of the seventh NMOS transistor N7 are connected; and a source of the seventh NMOS transistor N7 and a source of the fifth NMOS transistor N5 are grounded.

In this embodiment, the working principle of the write circuit is as follows: in a case where a high level is accessed to the first control terminal of the write circuit and a four-bit signal to be encrypted is input to the first input terminal of the write circuit, a one-bit binary signal is input to the input terminal of each first write cell and the input terminal of each second write cell; in each first write cell, the one-bit binary signal is subjected to phase inversion twice by means of an inverter formed by the first NMOS transistor and the first PMOS transistor and an inverter formed by the fourth PMOS transistor and the third NMOS transistor, and finally, the output terminal of each first write cell outputs a signal the same as the one-bit binary signal input to the input terminal of the first write cell; and in each second write cell, the one-bit binary signal is subjected to phase inversion by means of an inverter formed by the seventh PMOS transistor and the sixth PMOS transistor, and finally, the output terminal of each second write cell outputs a signal opposite in phase to the one-bit binary signal input to the input terminal of the second write cell, such that the write circuit converts the signal to be encrypted into two four-bit binary signals with opposite phases and outputs the two four-bit binary signals with opposite phases.

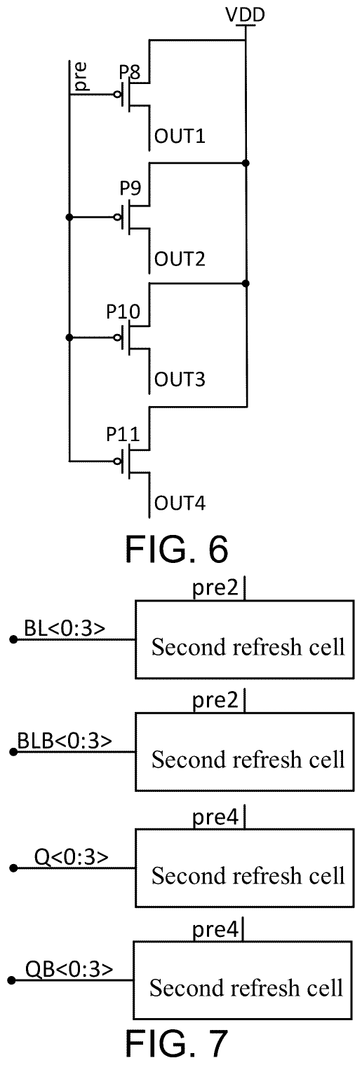

Embodiment 4: This embodiment is basically the same as Embodiment 2 and is different from Embodiment 2 in the following aspect: in this embodiment, as shown in FIGS. 5 and 6, the first refresh circuit includes three first refresh cells, wherein each first refresh cell has an input terminal and a group of output terminals; the input terminal of a 1^{st} first refresh cell is the first input terminal of the first refresh circuit, and the group of output terminals of the 1^{st} first refresh cell is the first group of output terminals of the first refresh circuit; the input terminal of a 2^{nd} first refresh cell is connected to the input terminal of a 3^{rd} first refresh cell, and a connecting terminal is the second input terminal of the first refresh circuit; the group of output terminals of the 2^{nd} first refresh cell is the second group of output terminals of the first refresh circuit; and the group of output terminals of the 3^{rd} first refresh cell is the third group of output terminals of the first refresh circuit. Each first refresh cell includes an eighth PMOS transistor P8, a ninth PMOS transistor P9, a tenth PMOS transistor P10 and an eleventh PMOS transistor P11, wherein a supply voltage VDD is accessed to a source of the eighth PMOS transistor P8, a source of the ninth PMOS transistor P9, a source of the tenth PMOS transistor P10 and a source of the eleventh PMOS transistor P11; a gate of the eighth PMOS transistor P8, a gate of the ninth PMOS transistor P9, a gate of the tenth PMOS transistor P10 and a gate of the eleventh PMOS transistor P11 are connected to a connecting terminal which is the input terminal of the first refresh cell; a drain of the eighth PMOS transistor P8 is a first output terminal of the first refresh cell, a drain of the ninth PMOS transistor P9 is a second output terminal of the first refresh cell, a drain of the tenth PMOS transistor P10 is a third output terminal of the first refresh cell, and a drain of the eleventh PMOS transistor P11 is a fourth output terminal of the first refresh cell; and the first output terminal, the second output terminal, the third output terminal and the fourth output terminal of the first refresh cell form the group of output terminals of the first refresh cell.

In this embodiment, the working principle of the first refresh circuit is as follows: in a case where a low level is accessed to the first input terminal of the first refresh circuit, the input terminal of each first refresh cell is at a low level, at this moment, the eighth PMOS transistor P8, the ninth PMOS transistor P9, the tenth PMOS transistor P10 and the eleventh PMOS transistor P11 in each first refresh cell are turned on, and the group of output terminals of the each first refresh cell outputs a pre-charge signal. In a case where the first input terminal of the first refresh circuit is at a high level, the first refresh circuit does not work.

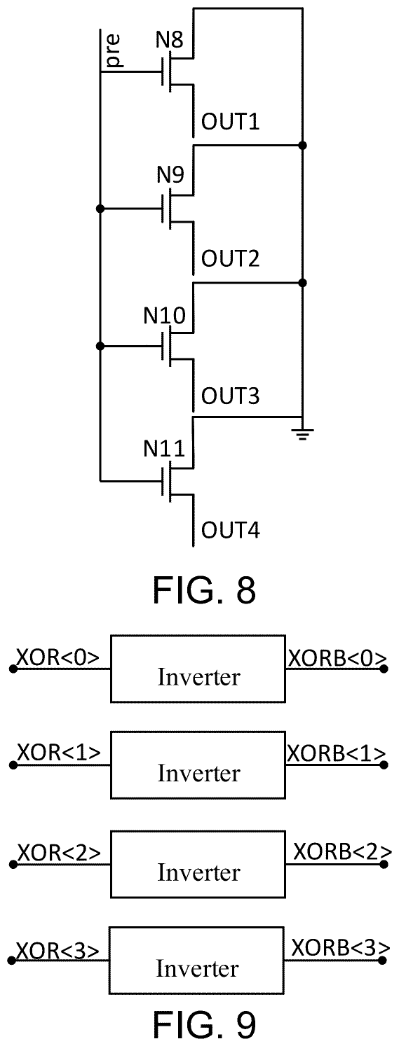

Embodiment 5: This embodiment is basically the same as Embodiment 2 and is different from Embodiment 2 in the following aspect: in this embodiment, as shown in FIGS. 7 and 8, the second refresh circuit includes four second refresh cells, wherein each second refresh cell has an input terminal and a group of output terminals; the input terminal of a 1^{st} second refresh cell and the input terminal of a 2^{nd} second refresh cell are connected to a connecting terminal which is the first input terminal of the second refresh circuit; the input terminal of a 3^{rd} second refresh cell and the input terminal of a 4^{th} second refresh cell are connected to a connecting terminal which is the second input terminal of the second refresh circuit; and the group of output terminals of the 1^{st} second refresh cell is the first group of output terminals of the second refresh circuit, the group of output terminals of the 2^{nd} second refresh cell is the second group of output terminals of the second refresh circuit, the group of output terminals of the 3^{rd} second refresh cell is the third group of output terminals of the second refresh circuit, and the group of output terminals of the 4^{th} second refresh cell is the fourth group of output terminals of the second refresh circuit. Each second refresh cell includes an eighth NMOS transistor N8, a ninth NMOS transistor N9, a tenth NMOS transistor N10 and an eleventh NMOS transistor N11, wherein a source of the eighth NMOS transistor N8, a source of the ninth NMOS transistor N9, a source of the tenth NMOS transistor N10 and a source of the eleventh NMOS transistor N11 are grounded; a gate of the eighth NMOS transistor N8, a gate of the ninth NMOS transistor N9, a gate of the tenth NMOS transistor N10 and a gate of the eleventh NMOS transistor N11 are connected to a connecting terminal which is the input terminal of the second refresh cell; a drain of the eighth NMOS transistor N8 is a first output terminal of the second refresh cell, a drain of the ninth NMOS transistor N9 is a second output terminal of the second refresh cell, a drain of the tenth NMOS transistor N10 is a third output terminal of the second refresh cell, and a drain of the eleventh NMOS transistor N11 is a fourth output terminal of the second refresh cell; and the first output terminal, the second output terminal, the third output terminal and the fourth output terminal of the second refresh cell form the group of output terminals of the second refresh cell.

In this embodiment, the working principle of the second refresh circuit is as follows: in a case where a high level is accessed to the first input terminal of the second refresh circuit, the input terminal of each second refresh cell is at a high level, at this moment, the eighth NMOS transistor N8, the ninth NMOS transistor N9, the tenth NMOS transistor N10 and the eleventh NMOS transistor N11 in each second refresh cell are turned on, and the group of output terminals of the each second refresh cell outputs a reset signal. In a case where the first input terminal of the second refresh circuit is at a low level, the second refresh circuit does not work.

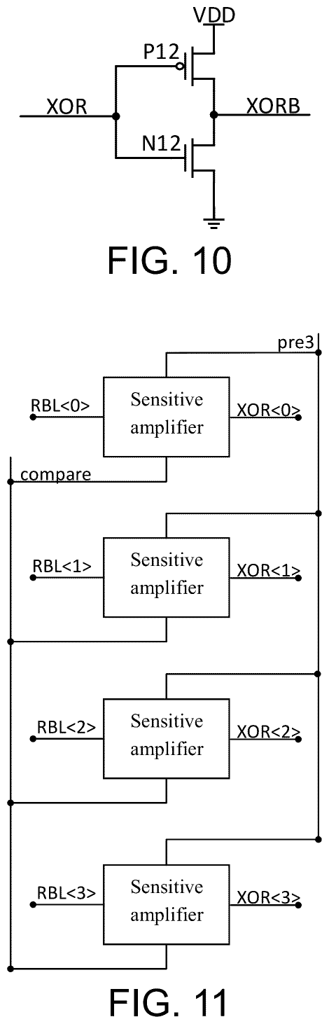

Embodiment 6: This embodiment is basically the same as Embodiment 2 and is different from Embodiment 2 in the following aspect: in this embodiment, as shown in FIGS. 9 and 10, the inverter array includes four inverters. Each inverter has an input terminal and an output terminal. The input terminal of a first inverter is a first input terminal of the inverter array, the input terminal of a second inverter is a second input terminal of the inverter array, the input terminal of a third inverter is a third input terminal of the inverter array, the input terminal of a fourth inverter is a fourth input terminal of the inverter array, and the first input terminal, the second input terminal, the third input terminal and the fourth input terminal of the inverter array form the first group of input terminals of the inverter array. The output terminal of the first inverter is a first output terminal of the inverter array, the output terminal of the second inverter is a second output terminal of the inverter array, the output terminal of the third inverter is a third output terminal of the inverter array, the output terminal of the fourth inverter is a fourth output terminal of the inverter array, and the first output terminal, the second output terminal, the third output terminal and the fourth output terminal of the inverter array forms the first group of output terminals of the inverter array. Each inverter includes a twelfth PMOS transistor P12 and a twelfth NMOS transistor N12, wherein a supply voltage is accessed to a source of the twelfth PMOS transistor P12; a gate of the twelfth PMOS transistor P12 and a gate of the twelfth NMOS transistor N12 are connected to a connecting terminal which is the input terminal of the inverter; a drain of the twelfth PMOS transistor P12 and a drain of the twelfth NMOS transistor N12 are connected to a connecting terminal which is the output terminal of the inverter; and a source of the twelfth NMOS transistor N12 is grounded.

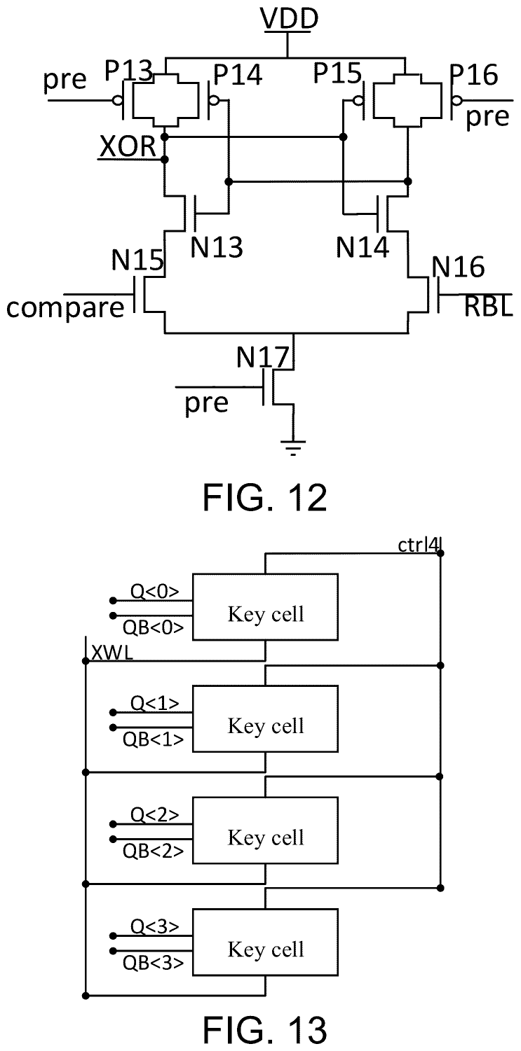

Embodiment 7: This embodiment is basically the same as Embodiment 2 and is different from Embodiment 2 in the following aspect: in this embodiment, as shown in FIGS. 11 and 12, the sensitive amplifier array includes four sensitive amplifiers. Each sensitive amplifier has three input terminals and an output terminal, wherein the three input terminals are referred to as a first input terminal, a second input terminal and a third input terminal, respectively. The first input terminals of the four sensitive amplifiers are connected to a connecting terminal which is the first input terminal of the sensitive amplifier array. The second input terminals of the four sensitive amplifiers are connected to a connecting terminal which is the second input terminal of the sensitive amplifier array. The third input terminal of a first sensitive amplifier is a first input terminal of the sensitive amplifier array, the third input terminal of a second sensitive amplifier is a second input terminal of the sensitive amplifier array, the third input terminal of a third sensitive amplifier is a third input terminal of the sensitive amplifier array, the third input terminal of a fourth sensitive amplifier is a fourth input terminal of the sensitive amplifier array, and first input terminal, the second input terminal, the third input terminal and the fourth input terminal of the sensitive amplifier array form the first group of input terminals of the sensitive amplifier array. The output terminal of the first sensitive amplifier is a first output terminal of the sensitive amplifier array, the output terminal of the second sensitive amplifier is a second output terminal of the sensitive amplifier array, the output terminal of the third sensitive amplifier is a third output terminal of the sensitive amplifier array, the output terminal of the fourth sensitive amplifier is a fourth output terminal of the sensitive amplifier, and the first output terminal, the second output terminal, the third output terminal and the fourth output terminal of the sensitive amplifier array form the first group of output terminals of the sensitive amplifier array. Each sensitive amplifier includes a thirteenth PMOS transistor P13, a fourteenth PMOS transistor P14, a fifteenth PMOS transistor P15, a sixteenth PMOS transistor P16, a thirteenth NMOS transistor N13, a fourteenth NMOS transistor N14, a fifteenth NMOS transistor N15, a sixteenth NMOS transistor N16 and a seventeenth NMOS transistor N17, wherein a supply voltage is accessed to a source of the thirteenth PMOS transistor P13, a source of the fourteenth PMOS transistor P14, a source of the fifteenth PMOS transistor P15 and a source of the sixteenth PMOS transistor P16; a gate of the thirteenth PMOS transistor P13, a gate of the sixteenth PMOS transistor P16 and a gate of the seventeenth NMOS transistor N17 are connected to a connecting terminal which is the second input terminal of the sensitive amplifier; a drain of the thirteenth PMOS transistor P13, a drain of the fourteenth PMOS transistor P14, a gate of the fifteenth PMOS transistor P15, a drain of the thirteenth NMOS transistor N13 and a gate of the fourteenth NMOS transistor N14 are connected to a connecting terminal which is the output terminal of the sensitive amplifier; a drain of the fifteenth PMOS transistor P15, a drain of the sixteenth PMOS transistor P16, a gate of the fourteenth PMOS transistor P14, a gate of the thirteenth NMOS transistor N13 and a drain of the fourteenth NMOS transistor N14 are connected; a drain of the fourteenth NMOS transistor N15 and a source of the thirteenth NMOS transistor N13 are connected; a drain of the sixteenth NMOS transistor N16 and a source of the fourteenth NMOS transistor N14 are connected; a gate of the fifteenth NMOS transistor N15 is the first input terminal of the sensitive amplifier; a gate of the sixteenth NMOS transistor N16 is the third input terminal of the sensitive amplifier; a source of the fifteenth NMOS transistor N15, a source of the sixteenth NMOS transistor N16 and a drain of the seventeenth NMOS transistor N17 are connected; and a source of the seventeenth NMOS transistor N17 is grounded.

In this embodiment, the working principle of the sensitive amplifier array is as follows: in a case where a four-bit low-level signal is input to the second input terminal of the sensitive amplifier array, a one-bit low-level signal is input to the second input terminal of each sensitive amplifier, at this moment, the thirteenth PMOS transistor P13 and the sixteenth PMOS transistor P16 in each sensitive amplifier are turned on, the seventeenth NMOS transistor N17 is turned off, and the sensitive amplifiers are refreshed, the first input terminal and the third input terminal in each sensitive amplifier are pre-charged to a high level, and the internal circuit state of the sensitive amplifiers is reset. In a case where a four-bit high-level signal is input to the second input terminal of the sensitive amplifier array, a one-bit high-level signal is input to the second input terminal of each sensitive amplifier, at this moment, the thirteenth PMOS transistor P13 and the sixteenth PMOS transistor P16 in each sensitive amplifier are turned on, the seventeenth NMOS transistor N17 is turned on, a voltage difference between the external threshold voltage compare input to the first input terminal of each sensitive amplifier and the voltage of the third input terminal of each sensitive amplifier is amplified, and based on positive feedback and amplification of an inverter formed by the fourteenth PMOS transistor P14 and the thirteenth NMOS transistor N13 and an inverter formed by the fifteenth PMOS transistor P15 and the fourteenth NMOS transistor N14, one-bit data are output by the output terminal of each sensitive amplifier.

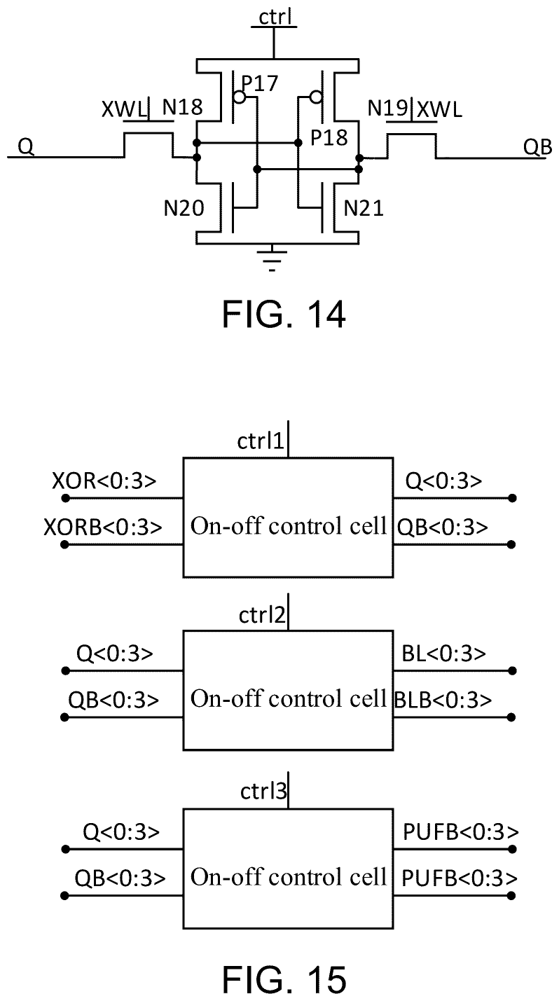

Embodiment 8: This embodiment is basically the same as Embodiment 2 and is different from Embodiment 2 in the following aspect: in this embodiment, as shown in FIGS. 13 and 14, the key row includes four key cells. Each key cell has an input terminal, a control terminal and two input-output terminals, wherein the two input-output terminals are referred to as a first input-output terminal and a second input-output terminal, respectively. The input terminals of the four key cells are connected to a connecting terminal which is the first input terminal of the key row. The control terminals of the four key cells are connected to a connecting terminal which is the control terminal of the key row. The first input-output terminal of a first key cell is a first input-output terminal of the key row, the first input-output terminal of a second key cell is a second input-output terminal of the key row, the first input-output terminal of a third key cell is a third input-output terminal of the key row, the first input-output terminal of a fourth key cell is a fourth input-output terminal of the key row, and the first input-output terminal, the second input-output terminal, the third input-output terminal and the fourth input-output terminal of the key row form the first group of input-output terminals of the key row. The second input-output terminal of the first key cell is a fifth input-output terminal of the key row, the second input-output terminal of the second key cell is a sixth input-output terminal of the key row, the second input-output terminal of the third key cell is a seventh input-output terminal of the key row, the second input-output terminal of the fourth key cell is an eighth input-output terminal of the key row, and the fifth input-output terminal, the sixth input-output terminal, the seventh input-output terminal and the eighth input-output terminal of the key row form the second group of input-output terminals of the key row. Each key cell includes a seventeenth PMOS transistor P17, an eighteenth PMOS transistor P18, an eighteenth NMOS transistor N18, a nineteenth NMOS transistor N19, a twentieth NMOS transistor N20 and a twenty-first NMOS transistor N21, wherein a source of the seventeenth PMOS transistor P17 and a source of the eighteenth PMOS transistor P18 are connected to a connecting terminal which is the control terminal of the key cell; a gate of the nineteenth NMOS transistor N18 and a gate of the nineteenth NMOS transistor N19 are connected to a connecting terminal which is the input terminal of the key row; a gate of the seventeenth PMOS transistor P17, a gate of the twentieth NMOS transistor N20, a drain of the eighteenth PMOS transistor P18, a drain of the twenty-first NMOS transistor N21 and a source of the nineteenth NMOS transistor N19 are connected; a gate of the eighteenth PMOS transistor P18, a gate of the twenty-first NMOS transistor N21, a drain of the seventeenth PMOS transistor P17, a drain of the twentieth NMOS transistor N20 and a source of the eighteenth NMOS transistor N18 are connected; a drain of the eighteenth NMOS transistor N18 is the first input-output terminal of the key cell; a drain of the nineteenth NMOS transistor N19 is the second input-output terminal of the key cell; and a source of the twentieth NMOS transistor N20 and a source of the twenty-first NMOS transistor N21 are grounded.

In this embodiment, the working principle of the key row is as follows: in a case where one-bit high-level data are input to the first control terminal of the key row, in each key cell, small differences generated in the production process of the MOS transistors are amplified into a pair of data with opposite phases by positive feedback of an inverter formed by the seventeenth PMOS transistor P17 and the twenty-first NMOS transistor N20 and an inverter formed by the eighteenth PMOS transistor P18 and the twenty-first NMOS transistor N21. In a case where a high level is accessed to the first input terminal of the key row, in each key cell, the eighteenth NMOS transistor N18 and the nineteenth NMOS transistor N19 are turned on, at this moment, the first group of input-output terminals of the key row outputs one of the two types of data with opposite phases, and the second group of input-output terminals of the key row outputs the other one of the two types of data with opposite phases.

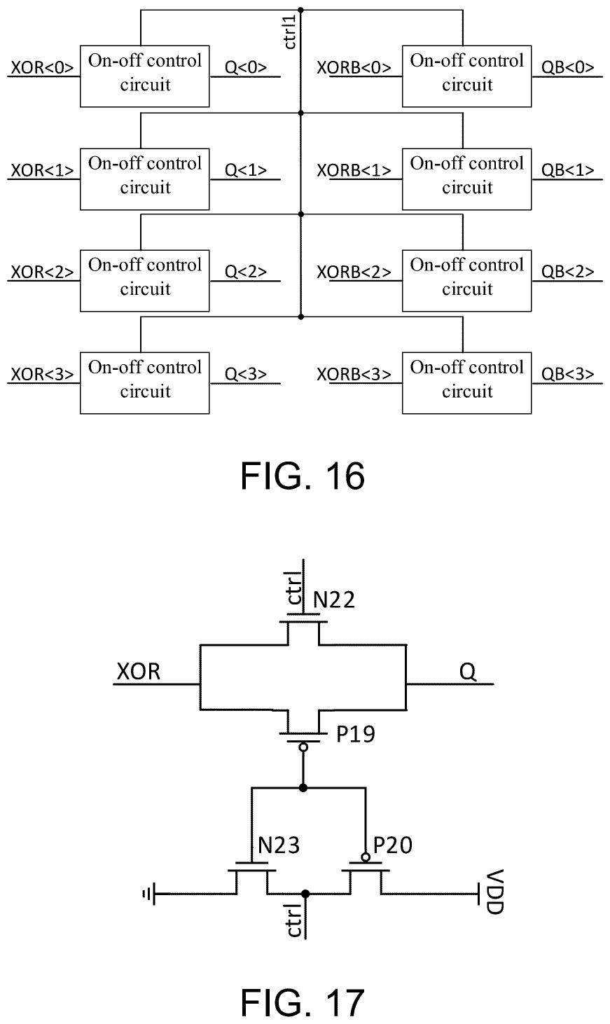

Embodiment 9: This embodiment is basically the same as Embodiment 2 and is different from Embodiment 2 in the following aspect: in this embodiment, as shown in FIGS. 15-17, the on-off control array includes three on-off control cells. Each on-off control cell has a control terminal, a first group of input terminals, a second group of input terminals, a first group of output terminals and a second group of output terminals. The control terminal of a first on-off control cell is the first control terminal of the on-off control array, the control terminal of a second on-off control cell is the second control terminal of the on-off control array, the control terminal of a third control cell is the third control terminal of the on-off control array, the first group of input terminals of the first on-off control cell is the first group of input terminals of the on-off control array, the second group of input terminals of the first on-off control cell is the second group of input terminals of the on-off control array, the first group of output terminals of the first on-off control cell is connected to the first group of input terminals of the second on-off control cell and the first group of input terminals of the third on-off control cell and connecting terminals form the first group of input-output terminals of the on-off control array, the second group of output terminals of the first on-off control cell is connected to the second group of input terminals of the second on-off control cell and the second group of input terminals of the third on-off control cell and connecting terminals form the second group of input-output terminals of the on-off control array, the first group of output terminals of the second on-off control cell is the first group of output terminals of the on-off control array, the second group of output terminals of the second on-off control cell is the second group of output terminals of the on-off control array, the first group of output terminals of the third on-off control cell is the third group of output terminals of the on-off control array, and the second group of output terminals of the third on-off control cell is the fourth group of output terminals of the on-off control array. Each on-off control cell includes eight on-off control circuits, wherein each on-off control circuit has a control terminal, an input terminal and an output terminal; the control terminals of the eight on-off control circuits are connected to a connecting terminal which is the control terminal of the on-off control cell; the input terminal of a first on-off control circuit is a first input terminal of the on-off control cell, the input terminal of a second on-off control circuit is a second input terminal of the on-off control cell, the input terminal of a third on-off control circuit is a third input terminal of the on-off control cell, the input terminal of a fourth on-off control circuit is a fourth input terminal of the on-off control cell, and the first input terminal, the second input terminal, the third input terminal and the fourth input terminal of the on-off control cell form the first group of input terminals of the on-off control cell; the input terminal of a fifth on-off control circuit is a fifth input terminal of the on-off control cell, the input terminal of a sixth on-off control circuit is a sixth input terminal of the on-off control cell, the input terminal of a seventh on-off control circuit is a seventh input terminal of the on-off control cell, the input terminal of an eighth on-off control circuit is an eighth input terminal of the on-off control cell, and the fifth input terminal, the sixth input terminal, the seventh input terminal and the eighth input terminal of the on-off control cell form the second group of input terminals of the on-off control cell; the output terminal of the first on-off control circuit is a first output terminal of the on-off control cell, the output terminal of the second on-off control circuit is a second output terminal of the on-off control cell, the output terminal of the third on-off control circuit is a third output terminal of the on-off control cell, the output terminal of the fourth on-off control circuit is a fourth output terminal of the on-off control cell, and the first output terminal, the second output terminal, the third output terminal and the fourth output terminal of the on-off control cell form the first group of output terminals of the on-off control cell; and the output terminal of the fifth on-off control circuit is a fifth output terminal of the on-off control cell, the output terminal of the sixth on-off control cell is a sixth output terminal of the on-off control cell, the output terminal of the seventh on-off control cell is a seventh output terminal of the on-off control cell, the output terminal of the eighth on-off control cell is an eighth output terminal of the on-off control cell, and the fifth output terminal, the sixth output terminal, the seventh output terminal and the eighth output terminal of the on-off control cell form the second group of output terminals of the on-off control cell. Each on-off control circuit includes a nineteenth PMOS transistor P19, a twentieth PMOS transistor P20, a twenty-second NMOS transistor N22 and a twenty-third NMOS transistor N23, wherein a drain of the nineteenth PMOS transistor P19 and a drain of the twenty-second NMOS transistor N22 are connected to a connecting terminal which is the input terminal of the on-off control circuit; a source of the nineteenth PMOS transistor P19 and a source of the twenty-second NMOS transistor N22 are connected to a connecting terminal which is the output terminal of the on-off control circuit; a gate of the nineteenth PMOS transistor P19, a gate of the twenty-third NMOS transistor N23 and a gate of the twentieth PMOS transistor P20 are connected; a supply voltage is accessed to a source of the twentieth PMOS transistor P20; a drain of the twentieth PMOS transistor P20, a drain of the twenty-third NMOS transistor N23 and a gate of the twenty-second NMOS transistor N22 are connected to a connecting terminal which is the control terminal of the on-off control circuit; and a source of the twenty-third NMOS transistor N23 is grounded.

In this embodiment, the working principle of the on-off control array is as follows: in a case where one-bit high-level data are input to the first control terminal of the on-off control array, in each on-off control cell, the one-bit high-level data are converted into one-bit low-level data by an inverter formed by the twenty-third NMOS transistor N23 and the twentieth PMOS transistor P20, the twenty-second NMOS transistor N22 and the nineteenth PMOS transistor P19 are turned on, the first group of input-output terminals of the on-off control array outputs a signal input to the first group of input terminals of the on-off control array. In a case where one-bit low-level data are input to the first control terminal of the on-off control array, the on-off control array does not work.

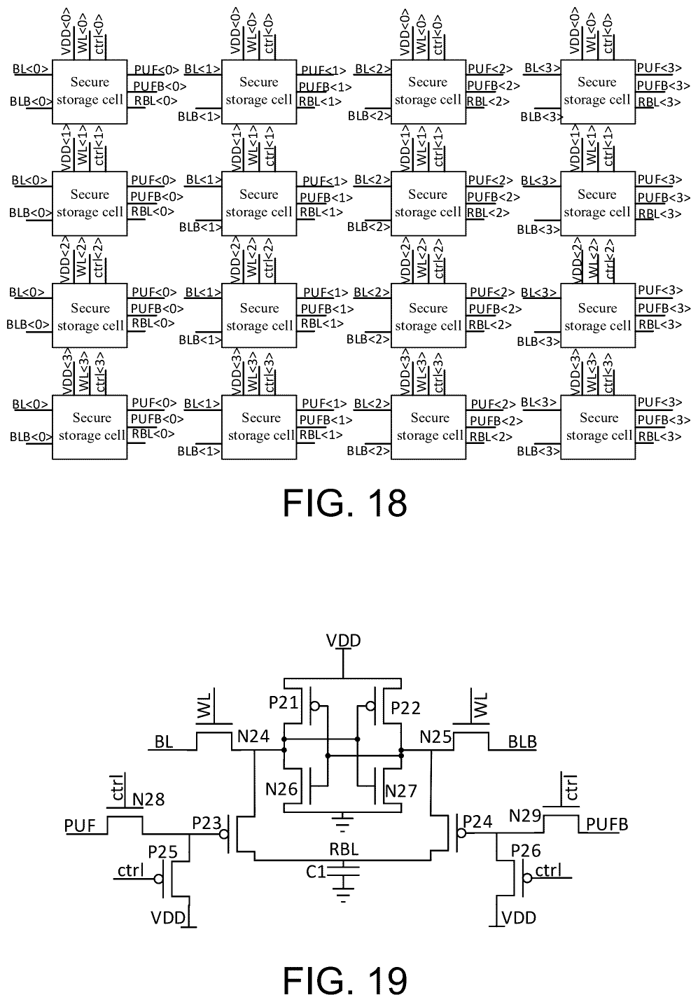

Embodiment 10: This embodiment is basically the same as Embodiment 2 and is different from Embodiment 2 in the following aspect: in this embodiment, as shown in FIGS. 18 and 19, the secure storage array includes sixteen secure storage cells which are distributed in four rows and four columns. Each secure storage cell has a first input terminal, a second input terminal, a third input terminal, a fourth input terminal, a fifth input terminal, a first input-output terminal and a second input-output terminal. The first input terminals of the four secure storage cells in a first row are connected to a connecting terminal which is a first input terminal of the secure storage array; the first input terminals of the four secure storage cells in a second row are connected to a connecting terminal which is a second input terminal of the secure storage array; the first input terminals of the four storage cells in a third row are connected to a connecting terminal which is a third input terminal of the secure storage array; the first input terminals of the four secure storage cells in a fourth row are connected to a connecting terminal which is a fourth input terminal of the cell storage array; and the first input terminal, the second input terminal, the third input terminal and the fourth input terminal of the secure storage array form the first group of input terminals of the secure storage array. The second input terminals of the four secure storage cells in the first row are connected to a connecting terminal which is a fifth input terminal of the secure storage array; the second input terminals of the four secure storage cells in the second row are connected to a connecting terminal which is a sixth input terminal of the secure storage array; the second input terminals of the four secure storage cells in the third row are connected to a connecting terminal which is a seventh input terminal of the secure storage cell; the second input terminals of the four secure storage cells in the fourth row are connected to a connecting terminal which is an eighth input terminal of the secure storage array; and the fifth input terminal, the sixth input terminal, the seventh input terminal and the eighth input terminal of the secure storage array form the second group of input terminals of the secure storage array. The third input terminals of the four secure storage cells in the first row are connected to a connecting terminal which is a ninth input terminal of the secure storage array; the third input terminals of the four secure storage cells in the second row are connected to a connecting terminal which is a tenth input terminal of the secure storage array; the third input terminals of the four secure storage cells in the third row are connected to a connecting terminal which is an eleventh input terminal of the secure storage array; the third input terminals of the four secure storage cells in the fourth row are connected to a connecting terminal which is a twelfth input terminal of the secure storage array; and the ninth input terminal, the tenth input terminal, the eleventh input terminal and the twelfth input terminal of the secure storage array form the third group of input terminals of the secure storage array. The fourth input terminals of the four secure storage cells in a first column are connected to a connecting terminal which is a thirteenth input terminal of the secure storage array; the fourth input terminals of the four secure storage cells of in a second column are connected to a connecting terminal which is a fourteenth input terminal of the secure storage array; the fourth input terminals of the four secure storage cells in a third column are connected to a connecting terminal which is a fifteenth input terminal of the secure storge array; the fourth input terminals of the four secure storage cells of in a fourth column are connected to a connecting terminal which is a sixteenth input terminal of the secure storage array; and the thirteenth input terminal, the fourteenth input terminal, the fifteenth input terminal and the sixteenth input terminal of the secure storage array from the fourth group of input terminals of the secure storage array. The fifth input terminals of the fourth storage cells in the first column are connected to a connecting terminal which is a seventeenth input terminal of the secure storage cell; the fifth input terminals of the four secure storage cells in the second column are connected to a connecting terminal which is an eighteenth input terminal of the secure storage array; the fifth input terminals of the four secure storage cells of in the third column are connected to a connecting terminal which is a nineteenth input terminal of the secure storage array; the fifth input terminals of the four secure storage cells in the fourth column are connected to a connecting terminal which is a twentieth input terminal of the secure storage array; and the seventeenth input terminal, the eighteenth input terminal, the nineteenth input terminal and the twentieth input terminal of the secure storage array form the fifth group of input terminals of the secure storage array. The first input-output terminals of the four secure storage cells in the first column are connected to a connecting terminal which is a first input-output terminal of the secure storage array; the first input-output terminals of the four secure storage cells in the second column are connected to a connecting terminal which is a second input-output terminal of the secure storage array; the first input-output terminals of the four secure storage cells in the third column are connected to a connecting terminal which is a third input-output terminal of the secure storage array; the first input-output terminals of the four secure storage cells in the fourth column are connected to a connecting terminal which is a fourth input-output terminal of the secure storage array; and the first input-output terminal, the second input-output terminal, the third input-output terminal and the fourth input-output terminal of the secure storage array form the first group of input-output terminals of the secure storage array. The second input-output terminals of the four secure storage cells in the first column are connected to a connecting terminal which is a fifth input-output terminal of the secure storage array; the second input-output terminals of the four secure storage cells in the second column are connected to a connecting terminal which is a sixth input-output terminal of the secure storage array; the second input-output terminals of the four secure storage cells in the third column are connected to a connecting terminal which is a seventh input-output terminal of the secure storage array; the second input-output terminals of the four secure storage cells in the fourth column are connected to a connecting terminal which is an eighth input-output terminal of the secure storage array; and the fifth input-output terminal, the sixth input-output terminal, the seventh input-output terminal and the eighth input-output terminal of the secure storage cell form the second group of input-output terminals of the secure storage array. The third input-output terminals of the four secure storage cells in the first column are connected to a connecting terminal which is a ninth input-output terminal of the secure storage array; the third input-output terminals of the four secure storage cells in the second column are connected to a connecting terminal which is a tenth input-output terminal of the secure storage array; the third input-output terminals of the four secure storage cells in the third column are connected to a connecting terminal which is an eleventh input-output terminal of the secure storage array; the third input-output terminals of the four secure storage cells in the fourth column are connected to a connecting terminal which is a twelfth input-output terminal of the secure storage array; and the ninth input-output terminal, the tenth input-output terminal, the eleventh input-output terminal and the twelfth input-output terminal of the secure storage array form the third group of input terminals of the secure storage array. Each secure storage cell includes a twenty-first PMOS transistor P21, a twenty-second PMOS transistor P22, a twenty-third PMOS transistor P23, a twenty-fourth PMOS transistor P24, a twenty-fifth PMOS transistor P25, a twenty-sixth PMOS transistor P26, a twenty-fourth NMOS transistor N24, a twenty-fifth NMOS transistor N25, a twenty-sixth NMOS transistor N26, a twenty-seventh NMOS transistor N27, a twenty-eighth NMOS transistor N8, a twenty-ninth NMOS transistor N29 and a first capacitor C1, wherein a source of the twenty-first PMOS transistor P21, a source of the twenty-second PMOS transistor P22, a source of the twenty-fifth NMOS transistor N25 and a source of the twenty-sixth NMOS transistor N26 are connected to a connecting terminal which is the first input terminal of the secure storage cell; a gate of the twenty-first PMOS transistor P21, a gate of the twenty-sixth NMOS transistor P26, a drain of the twenty-second PMOS transistor P22, a source of the twenty-seventh NMOS transistor N27, a source of the twenty-fifth NMOS transistor N25 and a source of the twenty-fourth PMOS transistor P24 are connected; a gate of the twenty-second PMOS transistor P22, a gate of the twenty-seventh NMOS transistor N27, a drain of the twenty-first PMOS transistor P21, a source of the twenty-sixth NMOS transistor N26, a source of the twenty-fourth NMOS transistor N24 and a source of the twenty-third PMOS transistor P23 are connected; a gate of the twenty-fourth NMOS transistor N24 and a gate of the twenty-fifth NMOS transistor N25 are connected to a connecting terminal which is the second input terminal of the secure storage cell; a drain of the twenty-fourth NMOS transistor N24 is the first input-output terminal of the secure storage cell; a drain of the twenty-fifth NMOS transistor N25 is the second input-output terminal of the secure storage cell; a gate of the twenty-third PMOS transistor P23, a source of the twenty-eighth NMOS transistor N28 and a drain of the twenty-fifth PMOS transistor P25 are connected; a gate of the twenty-fourth PMOS transistor P24, a source of the twenty-ninth NMOS transistor N29 and a drain of the twenty-sixth PMOS transistor P26 are connected; a drain of the twenty-eighth NMOS transistor N28 is the fourth input terminal of the secure storage cell; a drain of the twenty-ninth NMOS transistor N29 is the fifth input terminal of the secure storage cell; a gate of the twenty-eighth NMOS transistor N28, a gate of the twenty-ninth NMOS transistor N29, a gate of the twenty-fifth PMOS transistor P25 and a gate of the twenty-sixth PMOS transistor P26 are connected to a connecting terminal which is the third input terminal of the secure storage cell; a drain of the twenty-third PMOS transistor P23, a drain of the twenty-fourth PMOS transistor P24 and one terminal of the first capacitor C1 are connected to a connecting terminal which is the third input-output terminal of the secure storage cell; and a drain of the twenty-sixth NMOS transistor N26, a drain of the twenty-seventh NMOS transistor N27 and the other terminal of the first capacitor C1 are grounded.

In this embodiment, the working principle of the secure storage array is as follows: in a case where a high level is accessed to the first input terminal and the second input terminal of the secure storage cell in one column of the secure storage array, in each secure storage cell in this row, an inverter formed by the twenty-first PMOS transistor P21 and the twenty-sixth NMOS transistor N26 and an inverter formed by the twenty-second PMOS transistor P22 and the twenty-seventh NMOS transistor N27 store signals at the first input-output terminal and the second input-output terminal of each secure storage cell in this row, and at this moment, a pre-charge signal output by the first capacitor C1 by means of the first refresh circuit is charged to the supply voltage VDD, such that the third input terminal of each secure storage cell in this row has a high level signal; at this moment, data at the fourth input terminal and the fourth terminal of each secure storage cell in this row control on-off of the twenty-fifth PMOS transistor P25 and the twenty-sixth PMOS transistor P26, such that a discharge circuit is formed by the first capacitor C1 and the stored signals to realize data storage.

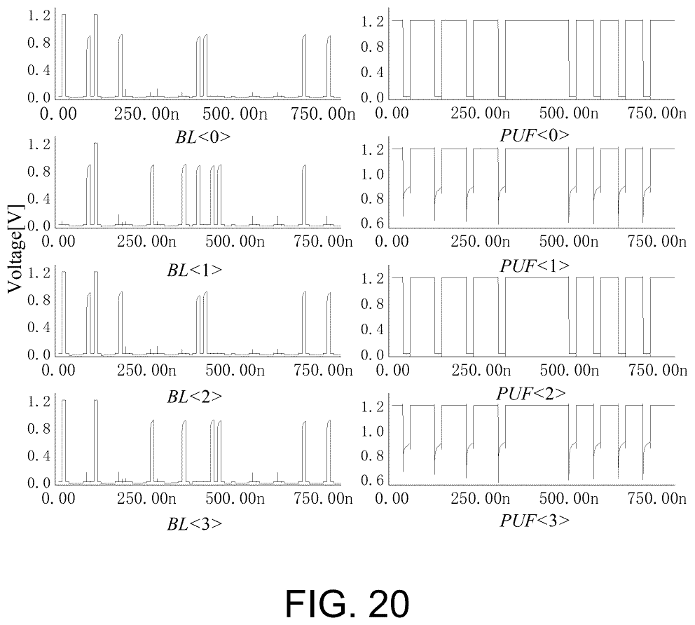

To verify the performance of the low-overhead encryption and decryption circuit based on hardware multiplexing provided by the invention, functional simulation is performed on the low-overhead encryption and decryption circuit based on hardware multiplexing provided by the invention by Spectre under a standard voltage 1.2 V of the 65 nm process of Taiwan Semiconductor Manufacturing Company, wherein a functional simulation oscillogram of the low-overhead encryption and decryption circuit based on hardware multiplexing provided by the invention is shown in FIG. 20. It may be known, by analyzing FIG. 20, that the low-overhead encryption and decryption circuit based on hardware multiplexing provided by the invention has a correct functional logic and may effectively realize data encryption and decryption.

What is claimed is:

1. A low-overhead encryption and decryption circuit based on hardware multiplexing, comprising: a secure storage array, a timing control module, a key row, a sensitive amplifier array, an inverter array, an on-off control array, a write circuit and two refresh circuits, wherein the two refresh circuits are referred to as a first refresh circuit and a second refresh circuits, respectively, and the secure storage array is realized based on a hardware multiplexing technique,
wherein when an encryption is needed, firstly, the timing control module controls the second refresh circuit to output a reset signal to refresh the secure storage array to reset a state of the secure storage array; then, when data to be encrypted are transmitted to the write circuit, the write circuit, under a control of the timing control module, converts the data to be encrypted into two types of data with opposite phases and outputs the two types of data with opposite phases to the secure storage array, and the secure storage array stores the two types of data with opposite phases output from the write circuit; then, the timing control module controls the first refresh circuit to output a pre-charge signal to pre-charge the secure storage array and controls the second refresh circuit to output a reset signal to refresh the key row to reset a state of the key row; then, the timing control module controls the key row to generate a pair of keys with opposite phases and transmits the pair of keys with opposite phases to the on-off control array; the on-off control array transmits the pair of keys with opposite phases transmitted from the key row to the secure storage array; the secure storage array performs an XOR operation on the pair of keys with opposite phases currently transmitted from the key row and the two types of data with opposite phases stored in the secure storage array to obtain a one-bit XOR value, and transmits the one-bit XOR value to the sensitive amplifier array; the sensitive amplifier array, under a control of the timing control module, shapes the one-bit XOR value output from the secure storage array to obtain a shaped XOR value and transmits the shaped XOR value to the inverter array; the inverter array performs a phase inversion on the shaped XOR value to obtain an XOR value with an opposite phase, and transmits the XOR value with the opposite phase to the on-off control array; the on-off control array transmits the shaped XOR value transmitted from the sensitive amplifier array and the XOR value with the opposite phase reversely transmitted from the inverter array to the secure storage array; and the secure storage array stores the shaped XOR value and the XOR value with the opposite phase as encrypted data, such that encryption is realized,
wherein when the encrypted data stored in the secure storage array need to be decrypted, firstly, the timing control module controls the first refresh circuit to output the pre-charge signal to pre-charge the secure storage array, and controls the second refresh circuit to output the reset signal to refresh the key row to reset the state of the key row; then, the timing control module controls the key row to generate the pair of keys with opposite phases and transmits the pair of keys with opposite phases to the on-off control array; the on-off control array transmits the pair of keys with opposite phases transmitted from the key row to the secure storage array; the secure storage array performs the XOR operation on the pair of keys with opposite phases received currently and the encrypted data stored in the secure storage array to obtain a one-bit initial value, and transmits the one-bit initial value to the sensitive amplifier array; the sensitive amplifier array, under the control of the timing control module, shapes the initial value to obtain a shaped initial value and transmits the shaped initial value to the inverter array; the inverter array performs the phase inversion on the shaped initial value to obtain an initial value with an opposite phase, and transmits the initial value with the opposite phase to the on-off control array; the on-off control array transmits the one-bit initial value output from the sensitive amplifier array and the initial value with the opposite phase output from the inverter array to the secure storage array; and the secure storage array stores the one-bit initial value and the initial value with the opposite phase, and at this moment, a pair of data stored in the secure storage array is the same as a pair of data input by the write circuit during encryption, such that data decryption is realized.

2. The low-overhead encryption and decryption circuit based on hardware multiplexing according to claim 1, wherein the write circuit has a group of input terminals, two groups of output terminals and a control terminal, wherein in the write circuit, four-bit binary data are input to the group of input terminals, each group of the two groups of output terminals is configured to output the four-bit binary data, the group of input terminals is referred to as a first group of input terminals, the two groups of output terminals are referred to as a first group of output terminals and a second group of output terminals, respectively, and the control terminal is referred to as a first control terminal,
wherein the first refresh circuit has two input terminals and three groups of output terminals, wherein in the first refresh circuit, the two input terminals are referred to as a first input terminal and a second input terminal respectively, each group of the three groups of output terminals is configured to output the four-bit binary data, and the three groups of output terminals are referred to as a first group of output terminals, a second group of output terminals and a third group of output terminals, respectively,
wherein second refresh circuit has two input terminals and four groups of output terminals, wherein in the second refresh circuit, the two input terminals are referred to as a first input terminal and a second input terminal, respectively, each group of the four groups of output terminals is configured to output the four-bit binary data, the four groups of output terminals are referred to as a first group of output terminals, a second group of second output terminals, a third group of output terminals and a fourth group of output terminals, respectively,
wherein the sensitive amplifier array has two input terminals, a group of input terminals and a group of output terminals, wherein in the sensitive amplifier array, the two input terminals are referred to as a first input terminal and a second terminal, respectively, the four-bit binary data are input to the group of input terminals, the group of input terminals is referred to as a first group of input terminal, and the group of output terminals is configured to output the four-bit binary data and is referred to as a first group of output terminals,
wherein the secure storage array has five groups of input terminals and three groups of input-output terminals, wherein in the secure storage array, the four-bit binary data are input to each group of the five groups of input terminals, each group of the three groups of input-output terminals is configured to output the four-bit binary data or allow the four-bit binary data to be input to the secure storage array, the five groups of input terminals are referred to as a first group of input terminals, a second group of input terminals, a third group of input terminals, a fourth group of input terminals and a fifth group of input terminals, respectively, and the three groups of input-output terminals are referred to as a first group of input-output terminals, a second group of input-output terminals and a third group of input-output terminals, respectively,
wherein the key row has an input terminal, two groups of input-output terminals and a control terminal, wherein in the key row, the input terminal is referred to as a first input terminal, each group of the two groups of input-output terminals is configured to output four-bit binary data or allow four-bit binary data to be input to the key row, the two groups of input-output terminals are referred to as a first group of input-output terminals and a second group of input-output terminals, respectively, and the control terminal is referred to as a first control terminal,
wherein the inverter array has a group of input terminals and a group of output terminals, wherein in the inverter, the four-bit binary data are input to the group of input terminals, the group of output terminals is configured to output the four-bit binary data, the group of input terminals is referred to as a first group of input terminals, and the group of output terminals is referred to as a first group of output terminals,
wherein the timing control module has ten output terminals, wherein in the timing control module, the ten output terminals are referred to as a first output terminal, a second output terminal, a third output terminal, a fourth output terminal, a fifth output terminal, a sixth output terminal, a seventh output terminal, an eighth output terminal, a ninth output terminal and a tenth output terminal, respectively,
wherein the timing control module is configured to control the secure storage array, the key row, the sensitive amplifier array, the inverter array, the on-off control array, the write circuit and the two refresh circuits to work coordinately, wherein the first output terminal, the second output terminal, the third output terminal, the fourth terminal and the fifth output terminal of the timing control module are configured to output control signals, respectively, wherein the sixth output terminal, the seventh output terminal, the eighth output terminal, the ninth output terminal and the tenth output terminal of the timing control module are configured to output refresh signals, respectively, wherein a control signal of the output signals output by the first output terminal of the timing control module is denoted as ctrl0, a control signal of the output signals output by the second output terminal of the timing control module is denoted as ctrl1, a control signal of the output signals output by the third output terminal of the timing control module is denoted as ctrl2, a control signal of the output signals output by the fourth output terminal of the timing control module is denoted as ctrl3, a control signal of the output signals output by the fifth output terminal of the timing control module is denoted as ctrl4, a refresh signal of the refresh signals output by the sixth output terminal of the timing control module is denoted as pre0, a refresh signal of the refresh signals output by the seventh output terminal of the timing control module is denoted as pre1, a refresh signal of the refresh signals output by the eighth output terminal of the timing control module is denoted as pre2, a refresh signal of the refresh signals output by the ninth output terminal of the timing control module is denoted as pre3, and a refresh signal of the refresh signals output by the tenth output terminal of the timing control module is denoted as pre4,
wherein the on-off control array has two groups of input terminals, four groups of output terminals, two groups of input-output terminals and three control terminals, wherein in the on-off control array, the four-bit binary data are input to each group of the two groups of input terminals, each group of the four groups of output terminals is configured to output four-bit binary data, each group of input-output terminals is configured to output the four-bit binary data or allow the four-bit binary data to be input to the on-off control array, the two groups of input terminals are referred to as a first group of input terminals and a second group of input terminals, respectively, the four groups of output terminals are referred to as a first group of output terminals, a second group of output terminals, a third group of output terminals and a fourth group of output terminals, respectively, the two groups of input-output terminals are referred to as a first group of input-output terminals and a second group of input-output terminals, respectively, and the three control terminals are referred to as a first control terminal, a second control terminal and a third control terminal, respectively,
wherein four-bit data to be encrypted are denoted as IN<0:3>, the four-bit data IN<0:3> to be encrypted are input to the first group of input terminals of the write circuit, the first group of output terminals of the write circuit is configured to output one of the two types of data with opposite phases, the second group of output terminals of the write circuit is configured to output the other one of the two types of data with opposite phases,
wherein the first group of output terminals of the write circuit is connected to the first group of input-output terminals of the secure storage array, the first group of output terminals of the second refresh circuit and the first group of output terminals of the on-off control array, wherein the second group of output terminals of the write circuit is connected to the second group of input-output terminals of the secure storage array, the second group of output terminals of the second refresh circuit and the second group of output terminals of the on-off control array, wherein the first control terminal of the write circuit is connected to the first output terminal of the timing control module, wherein the first input terminal of the first refresh circuit is connected to the sixth output terminal of the timing control module, the second input terminal of the first refresh circuit is connected to the seventh output terminal of the timing control module, the first group of output terminals of the first refresh circuit is connected to the third group of input-output terminals of the secure storage array and the first group of input terminals of the sensitive amplifier array, the second group of output terminals of the first refresh circuit is connected to the fourth group of input terminals of the secure storage array and the third group of output terminals of the on-off control array, the second group of output terminals of the first refresh circuit is configured to output the pre-charge signal, which is the four-bit binary data, wherein the third group of output terminals of the first refresh circuit is connected to the fifth group of input terminals of the secure storage array and the fourth group of output terminals of the on-off control array, the third group of output terminals of the first refresh circuit is configured to output the pre-charge signal, which is the four-bit binary data, wherein the first input terminal of the second refresh circuit is connected to the eighth output terminal of the timing control module, the second input terminal of the second refresh circuit is connected to the tenth output terminal of the timing control module, the third group of output terminals of the second refresh circuit is connected to the first group of input-output terminals of the key row and the first group of input-output terminals of the on-off control array, the third group of output terminals of the second refresh circuit is configured to output the reset signal, which is the four-bit binary data, wherein the fourth group of output terminals of the second refresh circuit is connected to the second group of input-output terminals of the key row and the second group of input-output terminals of the on-off control array, the fourth group of output terminals of the second refresh circuit is configured to output the reset signal, which is the four-bit binary data,
wherein the first input terminal of the sensitive amplifier array is configured to receive an external threshold voltage compare, the first group of output terminals of the sensitive amplifier array is configured to output the shaped XOR value, which is the four-bit binary data, wherein the second input terminal of the sensitive amplifier array is connected to the ninth output terminal of the timing control module, the first group of output terminals of the sensitive amplifier array is connected to the first group of input terminals of the inverter array and the first group of input terminals of the on-off control array, wherein the first group of input terminals of the secure storage array is configured to receive a four-bit voltage signal VDD<0:3>, wherein the second group of input terminals of the secure storage array is configured to receive a four-bit word line control signal WL<0:3>, wherein the third group of input terminals of the secure storage array is configured to receive a four-bit on-off control signal ctrl<0:3>; wherein the four-bit voltage signal VDD<0:3> is configured to control power-on and power-off of the secure storage array, wherein the four-bit word line control signal WL<0:3> is configured to control the secure storage array to store or not store data BL<0:3> input to the first input-output terminal of the secure storage array and data BLB<0:3> input to the second input-output terminal of the secure storage array, wherein the four-bit on-off control signal ctrl<0:3> is configured to control the secure storage array to store or not store data input to the fourth input terminal of the secure storage array and data input to the fifth input terminal of the secure storage array,
wherein the first control terminal of the key row is connected to the fifth output terminal of the timing control module, wherein the first input terminal of the key row is configured to receive a word line control signal XWL, and the word line control signal XWL is configured to control transmission of keys of the key row;
wherein the first group of output terminals of the inverter array is configured to output the shaped XOR value subjected to the phase inversion, the first group of output terminals of the inverter array is connected to first group of input terminals of the on-off control array, the first control terminal of the on-off control array is connected to the second output terminal of the timing control module, the second control terminal of the on-off control array is connected to the third output terminal of the timing control module, and the third control terminal of the on-off control array is connected the fourth output terminal of the timing control module.

3. The low-overhead encryption and decryption circuit based on hardware multiplexing according to claim 2, wherein the write circuit comprises four first write cells and four second write cells, wherein each of the four first write cells has an input terminal, an output terminal and a control terminal, each of the four second write cells has an input terminal, an output terminal and a control terminal, the control terminals of the four first write cells and the control terminals of the four second write cells are connected to a connecting terminal which is the first control terminal of the write circuit, an input terminal of a 1^{st} first write cell and an input terminal of a 1^{st} second write cell are connected to a connecting terminal which is a first input terminal of the write circuit, an input terminal of a 2^{nd} first write cell and an input terminal of a 2^{nd} second write cell are connected to a connecting terminal which is a second input terminal of the write circuit, an input terminal of a 3^{rd} first write cell and an input terminal of a 3^{rd} second write cell are connected to a connecting terminal which is a third input terminal of the write circuit, an input terminal of a 4^{th} first write cell and an input terminal of a 4^{th} second write cell are connected to a connecting terminal which is a fourth input terminal of the write circuit, and the first input terminal, the second input terminal, the third input terminal and the fourth input terminal of the write circuit form the first group of input terminals of the write circuit; wherein an output terminal of the 1^{st} first write cell is a first output terminal of the write circuit, an output terminal of the 2^{nd} first write cell is a second output terminal of the write circuit, an output terminal of the 3^{rd} first write cell is a third output terminal of the write circuit, an output terminal of the 4^{th} first write cell is a fourth output terminal of the write circuit, and the first output terminal, the second output terminal, the third output terminal and the fourth output terminal of the write circuit form the first group of output terminals of the write circuit; wherein an output terminal of the 1^{st} second write cell is a fifth output terminal of the write circuit, an output terminal of the 2^{nd} second write cell is a sixth output terminal of the write circuit, an output terminal of the 3^{rd} second write cell is a seventh output terminal of the write circuit, an output terminal of the 4^{th} second write cell is an eighth output terminal of the write circuit, and the fifth output terminal, the sixth output terminal, the seventh output terminal and the eighth output terminal of the write circuit form the second group of output terminals of the write circuit,
wherein each of the four first write cells comprises a first PMOS transistor, a second PMOS transistor, a third PMOS transistor, a fourth PMOS transistor, a first NMOS transistor, a second NMOS transistor, a third NMOS transistor and a fourth NMOS transistor, wherein a supply voltage is accessed to a source of the first PMOS transistor, a source of the second PMOS transistor and a source of the third PMOS transistor; wherein a gate of the first PMOS transistor and a gate of the first NMOS transistor are connected to a connecting terminal which is the input terminal of the four first write cells; a drain of the first PMOS transistor, a drain of the first NMOS transistor, a gate of the fourth PMOS transistor and a gate of the third NMOS transistor are connected; a drain of the second PMOS transistor, a gate of the third PMOS transistor and a drain of the second NMOS transistor are connected; a gate of the second PMOS transistor, a gate of the second NMOS transistor and a gate of the fourth NMOS transistor are connected to a connecting terminal which is the control terminal of the four first write cells; a drain of the third PMOS transistor and a source of the fourth PMOS transistor are connected; a drain of the fourth PMOS transistor and a drain of the third NMOS transistor are connected to a connecting terminal which is the output terminal of the four first write cells; a source of the third NMOS transistor and a drain of fourth NMOS transistor are connected; and a source of the first NMOS transistor, a source of the second NMOS transistor and a source of the fourth NMOS transistor are grounded,
wherein each of the four second write cells comprises a fifth PMOS transistor, a sixth PMOS transistor, a seventh PMOS transistor, a fifth NMOS transistor, a sixth NMOS transistor and a seventh NMOS transistor, wherein the supply voltage is accessed to a source of the fifth PMOS transistor and a source of the sixth PMOS transistor; a gate of the fifth PMOS transistor, a gate of the fifth NMOS transistor and a gate of the seventh NMOS transistor are connected to a connecting terminal which is the control terminal of the four second write cells; a drain of the fifth PMOS transistor, a gate of the sixth PMOS transistor and a drain of the fifth NMOS transistor are connected; a drain of the sixth PMOS transistor and a source of the seventh PMOS transistor are connected; a gate of the sixth NMOS transistor and a gate of the seventh PMOS transistor are connected to a connecting terminal which is the input terminal of the four second write cells; a source of the sixth NMOS transistor and a drain of the seventh PMOS transistor are connected to a connecting terminal which is the output terminal of the four second write cells; a drain of the sixth NMOS transistor and a drain of the seventh NMOS transistor are connected; and a source of the seventh NMOS transistor and a source of the fifth NMOS transistor are grounded.

4. The low-overhead encryption and decryption circuit based on hardware multiplexing according to claim 2, wherein the first refresh circuit comprises three first refresh cells, wherein each of the first refresh cells has an input terminal and a group of output terminals; wherein an input terminal of a 1^{st} first refresh cell is the first input terminal of the first refresh circuit, and a group of output terminals of the 1^{st} first refresh cell is the first group of output terminals of the first refresh circuit; an input terminal of a 2^{nd} first refresh cell and an input terminal of a 3^{rd} first refresh cell are connected to a connecting terminal which is the second input terminal of the first refresh circuit; wherein a group of output terminals of the 2^{nd} first refresh cell is the second group of output terminals of the first refresh circuit; and a group of output terminals of the 3^{rd} first refresh cell is the third group of output terminals of the first refresh circuit,
wherein each of the three first refresh cells comprises an eighth PMOS transistor, a ninth PMOS transistor, a tenth PMOS transistor and an eleventh PMOS transistor, wherein the supply voltage VDD is accessed to a source of the eighth PMOS transistor, a source of the ninth PMOS transistor, a source of the tenth PMOS transistor and a source of the eleventh PMOS transistor; a gate of the eighth PMOS transistor, a gate of the ninth PMOS transistor, a gate of the tenth PMOS transistor and a gate of the eleventh PMOS transistor are connected to a connecting terminal which is the input terminal of the three first refresh cells; wherein a drain of the eighth PMOS transistor is a first output terminal of the three first refresh cells, a drain of the ninth PMOS transistor is a second output terminal of the three first refresh cells, a drain of the tenth PMOS transistor is a third output terminal of the three first refresh cells, and a drain of the eleventh PMOS transistor is a fourth output terminal of the three first refresh cells; and the first output terminal, the second output terminal, the third output terminal and the fourth output terminal of the three first refresh cells form the group of output terminals of the three first refresh cells.

5. The low-overhead encryption and decryption circuit based on hardware multiplexing according to claim 2, wherein the second refresh circuit comprises four second refresh cells, wherein each of the four second refresh cells has an input terminal and a group of output terminals; wherein an input terminal of a 1^{st} second refresh cell and am input terminal of a 2^{nd} second refresh cell are connected to a connecting terminal which is the first input terminal of the second refresh circuit; an input terminal of a 3^{rd} second refresh cell and an input terminal of a 4^{th} second refresh cell are connected to a connecting terminal which is the second input terminal of the second refresh circuit; and a group of output terminals of the 1^{st} second refresh cell is the first group of output terminals of the second refresh circuit, a group of output terminals of the 2^{nd} second refresh cell is the second group of output terminals of the second refresh circuit, the group of output terminals of the 3^{rd} second refresh cell is the third group of output terminals of the second refresh circuit, and a group of output terminals of the 4^{th} second refresh cell is the fourth group of output terminals of the second refresh circuit,
wherein each of the four second refresh cells comprises an eighth NMOS transistor, a ninth NMOS transistor, a tenth NMOS transistor and an eleventh NMOS transistor, wherein a source of the eighth NMOS transistor, a source of the ninth NMOS transistor, a source of the tenth NMOS transistor and a source of the eleventh NMOS transistor are grounded; wherein a gate of the eighth NMOS transistor, a gate of the ninth NMOS transistor, a gate of the tenth NMOS transistor and a gate of the eleventh NMOS transistor are connected to a connecting terminal which is the input terminal of the four second refresh cells; wherein a drain of the eighth NMOS transistor is a first output terminal of the four second refresh cells, a drain of the ninth NMOS transistor is a second output terminal of the four second refresh cells, a drain of the tenth NMOS transistor is a third output terminal of the four second refresh cells, and a drain of the eleventh NMOS transistor is a fourth output terminal of the four second refresh cells; and the first output terminal, the second output terminal, the third output terminal and the fourth output terminal of the four second refresh cells form the group of output terminals of the four second refresh cells.

6. The low-overhead encryption and decryption circuit based on hardware multiplexing according to claim 2, wherein the inverter array comprises four inverters,
wherein each of the four inverters has an input terminal and an output terminal, wherein an input terminal of a first inverter is a first input terminal of the inverter array, an input terminal of a second inverter is a second input terminal of the inverter array, an input terminal of a third inverter is a third input terminal of the inverter array, an input terminal of a fourth inverter is a fourth input terminal of the inverter array, and the first input terminal, the second input terminal, the third input terminal and the fourth input terminal of the inverter array form the first group of input terminals of the inverter array,
wherein an output terminal of the first inverter is a first output terminal of the inverter array, an output terminal of the second inverter is a second output terminal of the inverter array, an output terminal of the third inverter is a third output terminal of the inverter array, an output terminal of the fourth inverter is a fourth output terminal of the inverter array, and the first output terminal, the second output terminal, the third output terminal and the fourth output terminal of the inverter array form the first group of output terminals of the inverter array,
wherein each of the four inverters comprises a twelfth PMOS transistor and a twelfth NMOS transistor, wherein a supply voltage is accessed to a source of the twelfth PMOS transistor; wherein a gate of the twelfth PMOS transistor and a gate of the twelfth NMOS transistor are connected to a connecting terminal which is the input terminal of the four inverters; a drain of the twelfth PMOS transistor and a drain of the twelfth NMOS transistor are connected to a connecting terminal which is the output terminal of the four inverters; and a source of the twelfth NMOS transistor is grounded.

7. The low-overhead encryption and decryption circuit based on hardware multiplexing according to claim 2, wherein the sensitive amplifier array comprises four sensitive amplifiers,
wherein each of the four sensitive amplifiers has three input terminals and an output terminal, wherein the three input terminals of the four sensitive amplifiers are referred to as a first input terminal, a second input terminal and a third input terminal, respectively wherein the first input terminals of the four sensitive amplifiers are connected to a connecting terminal which is the first input terminal of the sensitive amplifier array, wherein the second input terminals of the four sensitive amplifiers are connected to a connecting terminal which is the second input terminal of the sensitive amplifier array, wherein a third input terminal of a first sensitive amplifier is the first input terminal of the sensitive amplifier array, a third input terminal of a second sensitive amplifier is the second input terminal of the sensitive amplifier array, a third input terminal of a third sensitive amplifier is a third input terminal of the sensitive amplifier array, a third input terminal of a fourth sensitive amplifier is a fourth input terminal of the sensitive amplifier array, and first input terminal, the second input terminal, the third input terminal and the fourth input terminal of the sensitive amplifier array form the first group of input terminals of the sensitive amplifier array, wherein an output terminal of the first sensitive amplifier is a first output terminal of the sensitive amplifier array, an output terminal of the second sensitive amplifier is a second output terminal of the sensitive amplifier array, an output terminal of the third sensitive amplifier is a third output terminal of the sensitive amplifier array, an output terminal of the fourth sensitive amplifier is a fourth output terminal of the sensitive amplifier, and the first output terminal, the second output terminal, the third output terminal and the fourth output terminal of the sensitive amplifier array form the first group of output terminals of the sensitive amplifier array,
wherein each of the four sensitive amplifiers comprises a thirteenth PMOS transistor, a fourteenth PMOS transistor, a fifteenth PMOS transistor, a sixteenth PMOS transistor, a thirteenth NMOS transistor, a fourteenth NMOS transistor, a fifteenth NMOS transistor, a sixteenth NMOS transistor and a seventeenth NMOS transistor, wherein the supply voltage is accessed to a source of the thirteenth PMOS transistor, a source of the fourteenth PMOS transistor, a source of the fifteenth PMOS transistor and a source of the sixteenth PMOS transistor; wherein a gate of the thirteenth PMOS transistor, a gate of the sixteenth PMOS transistor and a gate of the seventeenth NMOS transistor are connected to a connecting terminal which is a second input terminal of the four sensitive amplifiers; a drain of the thirteenth PMOS transistor, a drain of the fourteenth PMOS transistor, a gate of the fifteenth PMOS transistor, a drain of the thirteenth NMOS transistor and a gate of the fourteenth NMOS transistor are connected to a connecting terminal which is an output terminal of the four sensitive amplifiers; a drain of the fifteenth PMOS transistor, a drain of the sixteenth PMOS transistor, a gate of the fourteenth PMOS transistor, a gate of the thirteenth NMOS transistor and a drain of the fourteenth NMOS transistor are connected; a drain of the fourteenth NMOS transistor and a source of the thirteenth NMOS transistor are connected; a drain of the sixteenth NMOS transistor and a source of the fourteenth NMOS transistor are connected; a gate of the fifteenth NMOS transistor is a first input terminal of the four sensitive amplifiers; a gate of the sixteenth NMOS transistor is a third input terminal of the four sensitive amplifiers; a source of the fifteenth NMOS transistor, a source of the sixteenth NMOS transistor and a drain of the seventeenth NMOS transistor are connected; and a source of the seventeenth NMOS transistor is grounded.

8. The low-overhead encryption and decryption circuit based on hardware multiplexing according to claim 2, wherein the key row comprises four key cells,
wherein each of the four key cells has an input terminal, a control terminal and two input-output terminals, wherein the two input-output terminals of the four key cells are referred to as a first input-output terminal and a second input-output terminal, respectively, wherein an input terminals of the four key cells are connected to a connecting terminal which is the first input terminal of the key row, wherein control terminals of the four key cells are connected to a connecting terminal which is the control terminal of the key row, wherein a first input-output terminal of a first key cell is a first input-output terminal of the key row, a first input-output terminal of a second key cell is a second input-output terminal of the key row, a first input-output terminal of a third key cell is a third input-output terminal of the key row, a first input-output terminal of a fourth key cell is a fourth input-output terminal of the key row, and the first input-output terminal, the second input-output terminal, the third input-output terminal and the fourth input-output terminal of the key row form a first group of input-output terminals of the key row, wherein a second input-output terminal of the first key cell is a fifth input-output terminal of the key row, a second input-output terminal of the second key cell is a sixth input-output terminal of the key row, a second input-output terminal of the third key cell is a seventh input-output terminal of the key row, a second input-output terminal of the fourth key cell is an eighth input-output terminal of the key row, and the fifth input-output terminal, the sixth input-output terminal, the seventh input-output terminal and the eighth input-output terminal of the key row form a second group of input-output terminals of the key row,
wherein each of the four key cells comprises a seventeenth PMOS transistor, an eighteenth PMOS transistor, an eighteenth NMOS transistor, a nineteenth NMOS transistor, a twentieth NMOS transistor and a twenty-first NMOS transistor, wherein a source of the seventeenth PMOS transistor and a source of the eighteenth PMOS transistor are connected to a connecting terminal which is a control terminal of the key cell; a gate of the nineteenth NMOS transistor and a gate of the nineteenth NMOS transistor are connected to a connecting terminal which is the input terminal of the key row; a gate of the seventeenth PMOS transistor, a gate of the twentieth NMOS transistor, a drain of the eighteenth PMOS transistor, a drain of the twenty-first NMOS transistor and a source of the nineteenth NMOS transistor are connected; a gate of the eighteenth PMOS transistor, a gate of the twenty-first NMOS transistor, a drain of the seventeenth PMOS transistor, a drain of the twentieth NMOS transistor and a source of the eighteenth NMOS transistor are connected; a drain of the eighteenth NMOS transistor is the first input-output terminal of the key cell; a drain of the nineteenth NMOS transistor is the second input-output terminal of the key cell; and a source of the twentieth NMOS transistor and a source of the twenty-first NMOS transistor are grounded.

9. The low-overhead encryption and decryption circuit based on hardware multiplexing according to claim 2, wherein the on-off control array comprises three on-off control cells,
wherein each of the three on-off control cells has a control terminal, a first group of input terminals, a second group of input terminals, a first group of output terminals and a second group of output terminals, wherein a control terminal of a first on-off control cell is the first control terminal of the on-off control array, a control terminal of a second on-off control cell is the second control terminal of the on-off control array, a control terminal of a third control cell is the third control terminal of the on-off control array, a first group of input terminals of the first on-off control cell is the first group of input terminals of the on-off control array, a second group of input terminals of the first on-off control cell is the second group of input terminals of the on-off control array, a first group of output terminals of the first on-off control cell are respectively connected to a first group of input terminals of the second on-off control cell and a first group of input terminals of the third on-off control cell at connecting terminals which are a first group of input-output terminals of the on-off control array, a second group of output terminals of the first on-off control cell are respectively connected to a second group of input terminals of the second on-off control cell and a second group of input terminals of the third on-off control cell at connecting terminals which are a second group of input-output terminals of the on-off control array, a first group of output terminals of the second on-off control cell is the first group of output terminals of the on-off control array, a second group of output terminals of the second on-off control cell is the second group of output terminals of the on-off control array, a first group of output terminals of the third on-off control cell is the third group of output terminals of the on-off control array, and a second group of output terminals of the third on-off control cell is the fourth group of output terminals of the on-off control array,
wherein each of the three on-off control cells comprises eight on-off control circuits, wherein each of the eight on-off control circuits has a control terminal, an input terminal and an output terminal; wherein the control terminals of the eight on-off control circuits are connected to a connecting terminal which is the control terminal of the three on-off control cells; an input terminal of a first on-off control circuit is a first input terminal of the three on-off control cells, an input terminal of a second on-off control circuit is a second input terminal of the three on-off control cells, an input terminal of a third on-off control circuit is a third input terminal of the three on-off control cells, an input terminal of a fourth on-off control circuit is a fourth input terminal of the three on-off control cells, and the first input terminal, the second input terminal, the third input terminal and the fourth input terminal of the three on-off control cells form the first group of input terminals of the three on-off control cells; wherein an input terminal of a fifth on-off control circuit is a fifth input terminal of the three on-off control cells, an input terminal of a sixth on-off control circuit is a sixth input terminal of the three on-off control cells, an input terminal of a seventh on-off control circuit is a seventh input terminal of the three on-off control cells, an input terminal of an eighth on-off control circuit is an eighth input terminal of the three on-off control cells, and the fifth input terminal, the sixth input terminal, the seventh input terminal and the eighth input terminal of the three on-off control cells form the second group of input terminals of the three on-off control cells; wherein an output terminal of the first on-off control circuit is a first output terminal of the three on-off control cells, an output terminal of the second on-off control circuit is a second output terminal of the three on-off control cells, an output terminal of the third on-off control circuit is a third output terminal of the three on-off control cells, an output terminal of the fourth on-off control circuit is a fourth output terminal of the three on-off control cells, and the first output terminal, the second output terminal, the third output terminal and the fourth output terminal of the three on-off control cells form the first group of output terminals of the three on-off control cells; and an output terminal of the fifth on-off control circuit is a fifth output terminal of the three on-off control cells, an output terminal of the sixth on-off control cell is a sixth output terminal of the three on-off control cells, an output terminal of the seventh on-off control cell is a seventh output terminal of the three on-off control cells, an output terminal of the eighth on-off control cell is an eighth output terminal of the three on-off control cells, and the fifth output terminal, the sixth output terminal, the seventh output terminal and the eighth output terminal of the three on-off control cells form the second group of output terminals of the three on-off control cells,
wherein each of the eight on-off control circuits comprises a nineteenth PMOS transistor, a twentieth PMOS transistor, a twenty-second NMOS transistor and a twenty-third NMOS transistor, wherein a drain of the nineteenth PMOS transistor and a drain of the twenty-second NMOS transistor are connected to a connecting terminal which is the input terminal of the eight on-off control circuits; a source of the nineteenth PMOS transistor and a source of the twenty-second NMOS transistor are connected to a connecting terminal which is the output terminal of the eight on-off control circuits; a gate of the nineteenth PMOS transistor, a gate of the twenty-third NMOS transistor and a gate of the twentieth PMOS transistor are connected; a supply voltage is accessed to a source of the twentieth PMOS transistor; a drain of the twentieth PMOS transistor, a drain of the twenty-third NMOS transistor and a gate of the twenty-second NMOS transistor are connected to a connecting terminal which is the control terminal of the eight on-off control circuits; and a source of the twenty-third NMOS transistor is grounded.

10. The low-overhead encryption and decryption circuit based on hardware multiplexing according to claim 2, wherein the secure storage array comprises sixteen secure storage cells which are distributed in four rows and four columns,
wherein each of the sixteen secure storage cells has a first input terminal, a second input terminal, a third input terminal, a fourth input terminal, a fifth input terminal, a first input-output terminal and a second input-output terminal, wherein first input terminals of four secure storage cells of the sixteen secure storage cells in a first row are connected to a connecting terminal which is a first input terminal of the secure storage array; first input terminals of four secure storage cells of the sixteen secure storage cells in a second row are connected to a connecting terminal which is a second input terminal of the secure storage array; first input terminals of four storage cells of the sixteen secure storage cells in a third row are connected to a connecting terminal which is a third input terminal of the secure storage array; first input terminals of four secure storage cells of the sixteen secure storage in a fourth row are connected to a connecting terminal which is a fourth input terminal of the cell storage array; and the first input terminal, the second input terminal, the third input terminal and the fourth input terminal of the secure storage array form the first group of input terminals of the secure storage array, wherein second input terminals of the four secure storage cells in the first row are connected to a connecting terminal which is a fifth input terminal of the secure storage array; second input terminals of the four secure storage cells in the second row are connected to a connecting terminal which is a sixth input terminal of the secure storage array; second input terminals of the four secure storage cells in the third row are connected to a connecting terminal which is a seventh input terminal of the secure storage cell; second input terminals of the four secure storage cells in the fourth row are connected to a connecting terminal which is an eighth input terminal of the secure storage array; and the fifth input terminal, the sixth input terminal, the seventh input terminal and the eighth input terminal of the secure storage array form the second group of input terminals of the secure storage array, wherein third input terminals of the four secure storage cells in the first row are connected to a connecting terminal which is a ninth input terminal of the secure storage array; third input terminals of the four secure storage cells in the second row are connected to a connecting terminal which is a tenth input terminal of the secure storage array; third input terminals of the four secure storage cells in the third row are connected to a connecting terminal which is an eleventh input terminal of the secure storage array; third input terminals of the four secure storage cells in the fourth row are connected to a connecting terminal which is a twelfth input terminal of the secure storage array; and the ninth input terminal, the tenth input terminal, the eleventh input terminal and the twelfth input terminal of the secure storage array form the third group of input terminals of the secure storage array, wherein fourth input terminals of four secure storage cells of the sixteen secure storage cells in a first column are connected to a connecting terminal which is a thirteenth input terminal of the secure storage array; fourth input terminals of four secure storage cells of the sixteen secure storage cells in a second column are connected to a connecting terminal which is a fourteenth input terminal of the secure storage array; fourth input terminals of four secure storage cells of the sixteen secure storage cells in a third column are connected to a connecting terminal which is a fifteenth input terminal of the secure storge array; fourth input terminals of four secure storage cells of the sixteen secure storage cells in a fourth column are connected to a connecting terminal which is a sixteenth input terminal of the secure storage array; and the thirteenth input terminal, the fourteenth input terminal, the fifteenth input terminal and the sixteenth input terminal of the secure storage array from the fourth group of input terminals of the secure storage array, wherein fifth input terminals of the fourth storage cells in the first column are connected to a connecting terminal which is a seventeenth input terminal of the secure storage cell; fifth input terminals of the four secure storage cells in the second column are connected to a connecting terminal which is an eighteenth input terminal of the secure storage array; fifth input terminals of the four secure storage cells of in the third column are connected to a connecting terminal which is a nineteenth input terminal of the secure storage array; fifth input terminals of the four secure storage cells in the fourth column are connected to a connecting terminal which is a twentieth input terminal of the secure storage array; and the seventeenth input terminal, the eighteenth input terminal, the nineteenth input terminal and the twentieth input terminal of the secure storage array form the fifth group of input terminals of the secure storage array, wherein first input-output terminals of the four secure storage cells in the first column are connected to a connecting terminal which is a first input-output terminal of the secure storage array; first input-output terminals of the four secure storage cells in the second column are connected to a connecting terminal which is a second input-output terminal of the secure storage array; first input-output terminals of the four secure storage cells in the third column are connected to a connecting terminal which is a third input-output terminal of the secure storage array; first input-output terminals of the four secure storage cells in the fourth column are connected to a connecting terminal which is a fourth input-output terminal of the secure storage array; and the first input-output terminal, the second input-output terminal, the third input-output terminal and the fourth input-output terminal of the secure storage array form the first group of input-output terminals of the secure storage array, wherein second input-output terminals of the four secure storage cells in the first column are connected to a connecting terminal which is a fifth input-output terminal of the secure storage array; second input-output terminals of the four secure storage cells in the second column are connected to a connecting terminal which is a sixth input-output terminal of the secure storage array; second input-output terminals of the four secure storage cells in the third column are connected to a connecting terminal which is a seventh input-output terminal of the secure storage array; second input-output terminals of the four secure storage cells in the fourth column are connected to a connecting terminal which is an eighth input-output terminal of the secure storage array; and the fifth input-output terminal, the sixth input-output terminal, the seventh input-output terminal and the eighth input-output terminal of the secure storage array form the second group of input-output terminals of the secure storage array, wherein third input-output terminals of the four secure storage cells in the first column are connected to a connecting terminal which is a ninth input-output terminal of the secure storage array; third input-output terminals of the four secure storage cells in the second column are connected to a connecting terminal which is a tenth input-output terminal of the secure storage array; third input-output terminals of the four secure storage cells in the third column are connected to a connecting terminal which is an eleventh input-output terminal of the secure storage array; third input-output terminals of the four secure storage cells in the fourth column are connected to a connecting terminal which is a twelfth input-output terminal of the secure storage array; and the ninth input-output terminal, the tenth input-output terminal, the eleventh input-output terminal and the twelfth input-output terminal of the secure storage array form the third group of input terminals of the secure storage array,
wherein each of the sixteen secure storage cells comprises a twenty-first PMOS transistor, a twenty-second PMOS transistor, a twenty-third PMOS transistor, a twenty-fourth PMOS transistor, a twenty-fifth PMOS transistor, a twenty-sixth PMOS transistor, a twenty-fourth NMOS transistor, a twenty-fifth NMOS transistor, a twenty-sixth NMOS transistor, a twenty-seventh NMOS transistor, a twenty-eighth NMOS transistor, a twenty-ninth NMOS transistor and a first capacitor, wherein a source of the twenty-first PMOS transistor, a source of the twenty-second PMOS transistor, a source of the twenty-fifth PMOS transistor and a source of the twenty-sixth PMOS transistor are connected to a connecting terminal which is a first input terminal of the sixteen secure storage cells; a gate of the twenty-first PMOS transistor, a gate of the twenty-sixth NMOS transistor, a drain of the twenty-second PMOS transistor, a source of the twenty-seventh NMOS transistor, a source of the twenty-fifth NMOS transistor and a source of the twenty-fourth PMOS transistor are connected; wherein a gate of the twenty-second PMOS transistor, a gate of the twenty-seventh NMOS transistor, a drain of the twenty-first PMOS transistor, a source of the twenty-sixth NMOS transistor, a source of the twenty-fourth NMOS transistor and a source of the twenty-third PMOS transistor are connected; wherein a gate of the twenty-fourth NMOS transistor and a gate of the twenty-fifth PMOS transistor are connected to a connecting terminal which is a second input terminal of the sixteen secure storage cells; a drain of the twenty-fourth NMOS transistor is a first input-output terminal of the sixteen secure storage cells; a drain of the twenty-fifth PMOS transistor is a second input-output terminal of the sixteen secure storage cells; a gate of the twenty-third PMOS transistor, a source of the twenty-eighth NMOS transistor and a drain of the twenty-fifth PMOS transistor are connected; wherein a gate of the twenty-fourth PMOS transistor, a source of the twenty-ninth NMOS transistor and a drain of the twenty-sixth PMOS transistor are connected; wherein a drain of the twenty-eighth NMOS transistor is a fourth input terminal of the sixteen secure storage cells; a drain of the twenty-ninth NMOS transistor is a fifth input terminal of the sixteen secure storage cells; wherein a gate of the twenty-eighth NMOS transistor, a gate of the twenty-ninth NMOS transistor, a gate of the twenty-fifth PMOS transistor and a gate of the twenty-sixth PMOS transistor are connected to a connecting terminal which is a third input terminal of the sixteen secure storage cells; wherein a drain of the twenty-third PMOS transistor, a drain of the twenty-fourth PMOS transistor and one terminal of the first capacitor are connected to a connecting terminal which is a third input-output terminal of the sixteen secure storage cells; and a drain of the twenty-sixth NMOS transistor, a drain of the twenty-seventh NMOS transistor and the other terminal of the first capacitor are grounded.
